(19) United States
(12) Patent Application Publication
(10) Pub. No.: US 2025/0230954 A1
(43) Pub. Date: Jul. 17, 2025

(54) CRYOGENIC SYSTEM INCLUDING INTEGRATED CRYOCOOLER AND DILUTION REFRIGERATOR

(71) Applicant: Maybell Quantum Industries, Inc., Denver, CO (US)

(72) Inventors: Kyle J. Thompson, Boulder, CO (US); Corban I. Tillemann-Dick, Denver, CO (US); Tyler James Plant, Thornton, CO (US)

(73) Assignee: Maybell Quantum Industries, Inc., Denver, CO (US)

(21) Appl. No.: 18/593,161

(22) Filed: Mar. 1, 2024

Related U.S. Application Data
(60) Provisional application No. 63/488,423, filed on Mar. 3, 2023.

(51) Int. Cl. F25B 9/14; H05K 7/20

(52) U.S. Cl. CPC F25B 9/145; H05K 7/20372

(57) ABSTRACT

There is provided a regenerative cryogenic system comprising a pulse tube assembly comprising one or more stages configured to generate cryogenic temperatures below 4.2 Kelvin, one or more flanges configured to provide vacuum interface or thermalization, the one or more flanges coupled to the pulse tube assembly, and a still pumping line integrated with the one or more of the flanges, the still pumping line configured to provide a flow path for still gas of a dilution refrigerator.

### CROSS-REFERENCE TO RELATED APPLICATIONS

This application claims the benefit under 35 U.S.C. § 119(e) of U.S. Provisional Patent Application No. 63/488,423 filed on Mar. 3, 2023, and titled “CRYOGENIC SYSTEM INCLUDING INTEGRATED CRYOCOOLER AND DILUTION REFRIGERATOR,” the contents of which is incorporated by reference herein in its entirety.

### BACKGROUND

Cryogenic systems may include a cryocooler (such as a pulse tube assembly) and a dilution refrigerator. Such a cryogenic system may be used for achieving low temperatures in a variety of scientific and industrial applications, for example, quantum computing applications.

### SUMMARY

According to aspects of the disclosure, there is provided a regenerative cryogenic system comprising a cryocooler configured to generate cryogenic temperatures, one or more flanges coupled to the cryocooler and a still pumping line integrated with the one or more flanges, the still pumping line configured to provide a flow path for still gas of a dilution refrigerator.

In some embodiments, the cryocooler is configured to generate cryogenic temperatures below 4.2 Kelvin (K). For example, the cryocooler may be configured to cool from a temperature range of >300K to about 2K. In some embodiments, the cryocooler may be configured to cool to a temperature of about 2.5K.

In some embodiments, the one or more flanges are configured to provide vacuum interface and/or thermalization.

In some embodiments, the regenerative cryogenic system further comprises a condensing line of the dilution refrigerator integrated with and configured to exchange heat with the cryocooler and the still pumping line, and the condensing line of the dilution refrigerator is configured to condense the still gas of the dilution refrigerator and the cryocooler is configured to provide cooling to the condensing line of the dilution refrigerator. In some embodiments, the gas may not be fully condensed at the cryocooler. Rather, some gas may be condensed at the cryocooler, and most of the gas may be initially condensed at further points of the system. In steady state, a majority of the gas may be condensed at the cryocooler.

In some embodiments, the condensing line of the dilution refrigerator is integrated with the cryocooler and the still pumping line by wrapping, brazing, or disposition a conduit of the still pumping line within gas flow or within a heat conductive block.

In some embodiments, the still pumping line is configured to cool the condensing line of the dilution refrigerator.

In some embodiments, the regenerative cryogenic system further comprises one or more heat exchangers integrated with the cryocooler, and the one or more heat exchangers are configured to provide heat exchange between the dilution refrigerator and the cryocooler. Cryocoolers such as pulse tubes may include heat exchangers for fluid that is not part of the pulse tube working fluid.

In some embodiments, the cryocooler comprises one or more pulse tubes.

In some embodiments, the cryocooler further comprises a 4K helium compressor, the regenerative cryogenic system further comprising an adsorber replacement system integrated with the 4K helium compressor, wherein the adsorber replacement system is configured to replace an adsorber of the 4K helium compressor without shutting down the 4K helium compressor.

In some embodiments, the regenerative cryogenic system further comprises a helium battery integrated with the cryocooler, wherein the helium battery is configured to store and release helium gas to maintain operation of the regenerative cryogenic system. In some embodiments, batteries other than helium batteries may be used, such as batteries of other high heat capacity materials,

According to aspects of the disclosure, there is provided a method of operating a cryogenic system comprising a cryocooler, a still pumping line of a dilution refrigerator, and a condensing line of the dilution refrigerator, the method comprising generating cryogenic temperatures using the cryocooler, exchanging heat between the condensing line and the cryocooler, and exchanging heat between the condensing line and the still pumping line.

In some embodiments, generating cryogenic temperatures using the cryocooler comprises generating cryogenic temperatures below 4.2 Kelvin.

In some embodiments, the method further comprising condensing still gas of the dilution refrigerator using the condensing line.

In some embodiments, exchanging heat between the condensing line and the cryocooler comprises cooling the condensing line using the cryocooler.

In some embodiments, exchanging heat between the condensing line and the still pumping line comprises cooling the condensing line using the still pumping line.

In some embodiments, the cryogenic system further comprises one or more flanges configured to provide vacuum interface and/or thermalization, the one or more flanges are coupled to the cryocooler, and the still pumping line is integrated with the one or more flanges.

According to aspects of the disclosure, there is provided a cryogenic system comprising means for generating cryogenic temperatures, one or more flanges configured to provide vacuum interface and/or thermalization, the one or more flanges coupled to the means for generating the cryogenic temperatures, and a still pumping line integrated with the one or more flanges, the still pumping line configured to provide a flow path for still gas of a dilution refrigerator.

In some embodiments, the cryogenic system further comprises a condensing line of a dilution refrigerator, wherein the condensing line of the dilution refrigerator is configured to exchange heat with the means for generating the cryogenic temperatures and the still pumping line and condense the still gas of the dilution refrigerator.

In some embodiments, the condensing line of the dilution refrigerator comprises a first portion integrated with and configured to exchange heat with the still pumping line and a second portion integrated with and configured to exchange heat with the means for generating the cryogenic temperatures and the still pumping line is configured to cool the condensing line of the dilution refrigerator.

In some embodiments, the condensing line of the dilution refrigerator is integrated with the means for generating the cryogenic temperatures and the still pumping line by wrapping, brazing, or disposition a conduit of the still pumping line within gas flow or within a heat conductive block.

According to aspects of the disclosure, there is provided a regenerative cryogenic system comprising a pulse tube assembly comprising one or more stages configured to generate cryogenic temperatures below 4.2 Kelvin, one or more flanges configured to provide vacuum interface or thermalization, the one or more flanges coupled to the pulse tube assembly, and a still pumping line integrated with the one or more flanges, the still pumping line configured to provide a flow path for still gas of a dilution refrigerator.

In some embodiments, the still pumping line is configured to provide the flow path for the still gas of the dilution refrigerator to be pumped out of the regenerative cryogenic system.

In some embodiments, the regenerative cryogenic further comprises a dilution refrigerator condensing line integrated with and configured to exchanged heat with the pulse tube assembly and the still pumping line, and the dilution refrigerator condensing line is configured to condense the still gas of the dilution refrigerator and the pulse tube assembly is configured to provide cooling to the dilution refrigerator condensing line.

In some embodiments, the dilution refrigerator condensing line is integrated with the pulse tube assembly and still pumping line by wrapping, brazing, or disposition within gas flow.

In some embodiments, the dilution refrigerator condensing line comprises a first portion integrated with and configured to exchange heat with the still pumping line and a second portion integrated with and configured to exchange heat with the pulse tube assembly.

In some embodiments, the still pumping line is configured to cool the dilution refrigerator condensing line.

In some embodiments, the dilution refrigerator condensing line is integrated with the pulse tube assembly and still pumping line by wrapping, brazing, or disposition within gas flow.

In some embodiments, the regenerative cryogenic system further comprises one or more heat exchangers integrated with the pulse tube assembly, wherein the one or more heat exchangers are configured to provide heat exchange between the dilution refrigerator and the pulse tube assembly.

In some embodiments, the pulse tube assembly comprises a 4K helium compressor and the regenerative cryogenic system further comprises an adsorber replacement system integrated with the 4K helium compressor, wherein the adsorber replacement system is configured to replace an adsorber of the 4K helium compressor without shutting down the 4K helium compressor.

In some embodiments, the regenerative cryogenic system further comprises a helium battery integrated with the pulse tube assembly, wherein the helium battery is configured to store and release helium gas to maintain operation of the regenerative cryogenic system.

According to aspects of the disclosure, there is provided a cryogenic system comprising a cryocooler comprising one or more stages configured to generate cryogenic temperatures, one or more flanges configured to provide vacuum interface or thermalization, the one or more flanges coupled to the cryocooler, and a still pumping line integrated with the one or more flanges, the still pumping line configured to provide a flow path for still gas of a dilution refrigerator.

In some embodiments, the cryocooler is configured to generate cryogenic temperatures below 4.2 Kelvin.

In some embodiments, the cryogenic system further comprises a dilution refrigerator condensing line configured to exchange heat with the cryocooler and the still pumping line and the dilution refrigerator condensing line is configured to condense the still gas of the dilution refrigerator and the cryocooler is configured to provide to the dilution refrigerator condensing line.

In some embodiments, the dilution refrigerator condensing line comprises a first portion integrated with and configured to exchange heat with the still pumping line and a second portion integrated with and configured to exchange heat with the cryocooler.

In some embodiments, the still pumping line is configured to cool the dilution refrigerator condensing line.

In some embodiments, the dilution refrigerator condensing line is integrated with the cryocooler and the still pumping line by wrapping, brazing, or disposition within gas flow.

According to aspects of the disclosure, there is provided a cryogenic system comprising means for generating cryogenic temperatures, one or more flanges configured to provide vacuum interface or thermalization, the one or more flanges coupled to the means for generating cryogenic temperatures, and a still pumping line integrated with the one or more flanges, the still pumping line configured to provide a flow path for still gas of a dilution refrigerator. In some embodiments, the means for generating cryogenic temperatures is configured to generate cryogenic temperatures below 4.2 Kelvin.

In some embodiments, the cryogenic system further comprises a dilution refrigerator condensing line configured to exchange heat with the means for generating cryogenic temperatures and the still pumping line and the dilution refrigerator condensing line is configured to condense the still gas of the dilution refrigerator and the means for generating cryogenic temperatures is configured to provide cooling to the dilution refrigerator condensing line.

In some embodiments, the dilution refrigerator condensing line comprises a first portion integrated with and configured to exchange heat with the still pumping line and a second portion integrated with and configured to exchange heat with the means for generating cryogenic temperatures and the still pumping line is configured to cool the dilution refrigerator condensing line.

In some embodiments, the dilution refrigerator condensing line is integrated with the means for generating cryogenic temperatures and still pumping line by wrapping, brazing, or disposition within gas flow.

According to aspects of the disclosure, there is provided a method of manufacturing a cryogenic system, the method comprising coupling one or more flanges to a cryocooler and integrating a still pumping line with the one or more flanges.

### BRIEF DESCRIPTION OF DRAWINGS

The accompanying drawings are not intended to be drawn to scale. In the drawings, each identical or nearly identical component that is illustrated in various figures is represented by a like numeral. For purposes of clarity, not every component may be labeled in every drawing. In the drawings:

FIG. 1 is a schematic diagram of a cryogenic system including a cryocooler integrated with a dilution refrigerator, in accordance with some embodiments described herein; and

FIGS. 2A-2D show illustrative components of a cryogenic system including a cryocooler integrated with a dilution refrigerator, such as the cryogenic system of FIG. 1, in accordance with some embodiments described herein.

FIG. 3 is a schematic diagram of a closed-cycle dilution refrigerator, in accordance with some embodiments described herein.

FIG. 4 is a schematic diagram of helium cleaning devices in the dilution refrigerator of FIG. 3, in accordance with some embodiments described herein.

FIG. 5 is a schematic diagram of a cooldown turbo charger device in the dilution refrigerator of FIG. 3, in accordance with some embodiments described herein.

FIG. 6 is a schematic diagram of a still including a device to separate ³He and ⁴He using second sound effects, in accordance with some embodiments described herein.

FIG. 7A shows illustrative components of a removable dilution insert for the dilution refrigerator of FIG. 3, in accordance with some embodiments described herein.

FIG. 7B is a view of an illustrative thermalization plate insert of the removable dilution insert of FIG. 7A, in accordance with some embodiments described herein.

FIG. 7C is a cross-sectional view of an illustrative integrated heat exchanger showing channels for helium flow, in accordance with some embodiments described herein.

FIG. 7D is an image of a high surface area material for use in an integrated heat exchanger, in accordance with some embodiments described herein.

FIG. 7E is an illustrative implementation of a continuous heat exchanger and discrete heat exchanger of the dilution refrigerator of FIG. 3, in accordance with some embodiments described herein.

FIGS. 8A-8F are schematic diagrams of illustrative ⁴He film separation devices, in accordance with some embodiments described herein.

FIG. 9A is an image of sintered metal particles for use in a heat exchanger.

FIG. 9B is an image of nanowires for use in a heat exchanger, in accordance with some embodiments described herein.

FIG. 9C is an image of a nanocluster for use in a heat exchanger, in accordance with some embodiments described herein.

FIG. 9D includes images of different nanopellets for use in a heat exchanger in accordance with some embodiments described herein.

FIG. 10A is a schematic diagram of an illustrative vibration isolation system for use in the dilution refrigerator of FIG. 3, in accordance with some embodiments described herein.

FIG. 10B shows an illustrative spring for use in the vibration isolation system of FIG. 10A, in accordance with some embodiments described herein.

FIG. 11 is a side view of an illustrative external support rack and integrated lift configured to raise and lower portions of the vacuum chamber, in accordance with some embodiments described herein.

FIG. 12A is a side view of an illustrative implementation of the dilution refrigerator of FIG. 3 including elements configured to provide tool-free assembly of the vacuum chamber and access to the experimental volume, in accordance with some embodiments described herein.

FIGS. 12B and 12C are views of integrated latches in open and closed positions, respectively, configured to provide tool-free assembly of the vacuum chamber, in accordance with some embodiments described herein.

FIG. 13 is an exterior view of a housing configured to support a dilution refrigerator, in accordance with some embodiments described herein.

FIG. 14A is a schematic diagram of an inverted dilution refrigerator, in accordance with some embodiments described herein.

FIGS. 14B and 14C are schematic diagrams of illustrative components of an inverted dilution refrigerator, in accordance with some embodiments described herein.

FIG. 15 is a schematic diagram of a distributed cooling system, in accordance with some embodiments described herein.

FIG. 16 depicts, schematically, an illustrative computing device on which aspects of the technology described herein may be implemented.

### DETAILED DESCRIPTION

Aspects of the disclosure relate to the field of cryogenics. In some embodiments, there is provided a pulse tube cryogenic system integrated with a dilution refrigerator and related methods. Aspects of the disclosure, including a pulse tube cryogenic system integrated with a dilution refrigerator and related methods, address limitations associated with conventional existing arrangements of cryogenic systems and methods. Aspects of the disclosure further provide more efficient, effective, and compact cryogenic systems and methods, in order to achieve low temperatures. In some embodiments, low temperatures may include temperatures suitable for scientific and industrial applications, for example, quantum computing applications, and may include temperatures below 300 mK. Embodiments of the disclosure described herein may provide more efficient, effective, and compact systems and methods through better integration of a regenerative cycle cooler, such as a 4.2 Kelvin Pulse Tube with a sub-Kelvin dilution unit.

Pulse tube cryogenic systems and dilution refrigerators are two techniques for achieving low temperatures in a variety of scientific and industrial applications. A pulse tube cryogenic system may comprise a specialized type of modified sterling engine that operates by compressing and expanding helium gas through a series of valves, heat exchangers, and regenerators, to ultimately generate an intermediate low temperature. For example, intermediate low temperatures may comprise temperatures around 2-4.2 Kelvin. In other embodiments, the intermediate low temperature may be as high as about 7 Kelvin, about 10 Kelvin, or about 50 Kelvin.

A dilution refrigerator may operate using a mixture of helium-3 and helium-4 isotopes to achieve low temperatures. For example, low temperatures may include temperatures as low as a few millikelvin. In some embodiments, a mixture is first liquefied by cooling it with an alternative system. For example, this liquefied mixture may be initially cooled through using a Joule-Thomson expander and then a series of heat exchangers, until a critical temperature is reached. In some embodiments, this critical temperature may be around 870mK. At the critical temperature, a spontaneous phase separation may occur into two fractions, a first fraction rich in helium-3 and a second fraction rich in helium-4. The dilute phase may be pumped with sufficient pressure and at appropriate temperatures. When the dilute phase is pumped, the natural ratio in the dilute phase may be disrupted due to the higher vapor pressure of helium-3. The heat of mixing associated with helium-3 crossing the phase boundary to correct this ratio may allow a cryogenic system to cool to low temperatures, such as temperatures as low as a few millikelvin. The resulting cooling power provided by the cryogenic system may be used to cool and study various materials and phenomena, such as superconductivity and quantum mechanics.

In some embodiments, to operate, a helium-3 and helium-4 mixture of a dilution refrigerator is first be brought to an intermediate low temperature, for example, of about 4.2 Kelvin or lower. According to various embodiments, techniques for achieving this intermediate low temperature or initializing temperature, include, among other techniques, helium baths, staged nitrogen-helium baths, Gifford-McMahon cryocoolers (GM), GM-style pulse tubes, or Stirling-style pulse tubes (together, “pulse tubes”). In some conventional systems, use of a dilution unit in combination with a GM pulse tube is may be a preferred approach for various reasons.

However, conventional arrangements using pulse tube cryogenic systems and dilution refrigerators present several limitations, including large system footprints, inefficient thermalization of incoming helium gas, and cold gas returning to room temperature through the still pumping line, among other limitations. Such limitations reduce overall system efficiency of conventional cryogenic systems.

Aspects of the disclosure address the limitations presented by conventional cryogenic systems by integrating a dilution refrigerator with a pulse tube or other 4K cryogenic system, for example, by integrating a still pumping line for a dilution refrigerator into a same flange as a pulse tube or other 4K cryogenic system. A cryogenic system with these components integrated provides better thermalization of incoming helium gas, improved cooling performance, improved energy efficiency, and results in a significantly more compact solution for generating sub-Kelvin cryogenic temperatures, as compared to conventional cryogenic systems.

The inventors have further recognized that conventional pulse tubes may be unnecessarily large, and that integrating a dilution refrigerator with a pulse tube or other 4K cryogenic system, such as by integrating a still pumping line into a vacuum interface of a pulse tube results in several significant benefits, including reduced size and improved thermal performance. The inventors have further recognized several other improvements to 4.2 Kelvin systems.

The contents of U.S. patent application Ser. No. 17/860,909 filed on Jul. 8, 2022, and titled “INTEGRATED DILUTION REFRIGERATORS,” is incorporated by reference herein in its entirety. U.S. patent application Ser. No. 17/860,909 describes some embodiments of cryogenic systems, including dilution refrigerators, pulse tubes, and other cryocoolers or 4K cryogenic systems.

### I. Integrated Cryocooler and Dilution Refrigerator

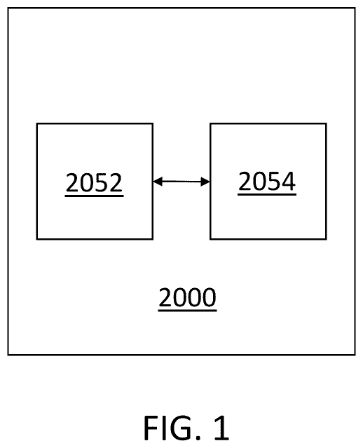

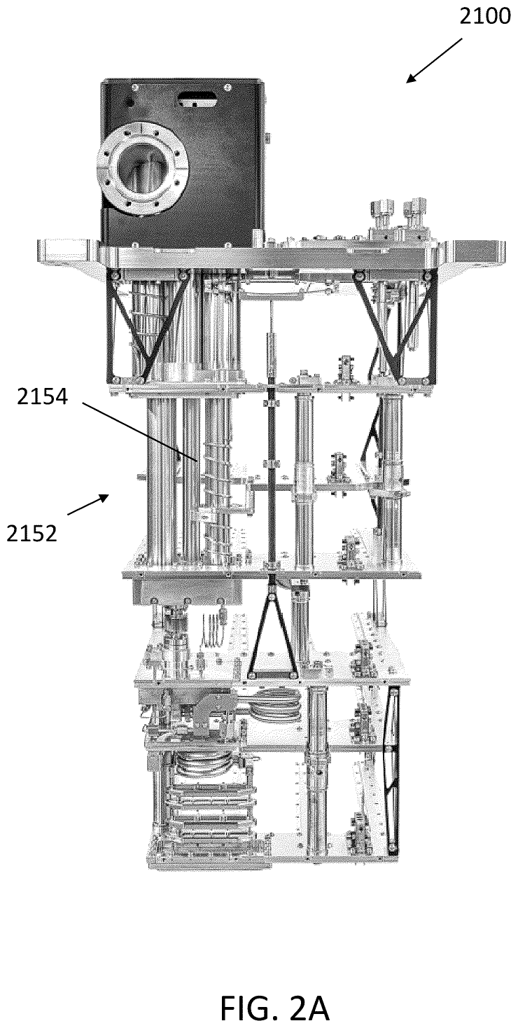

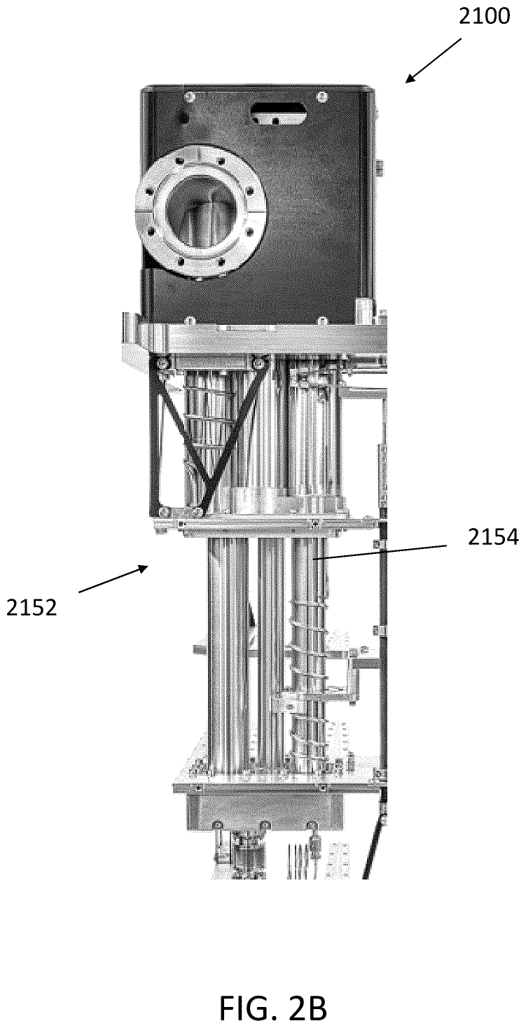

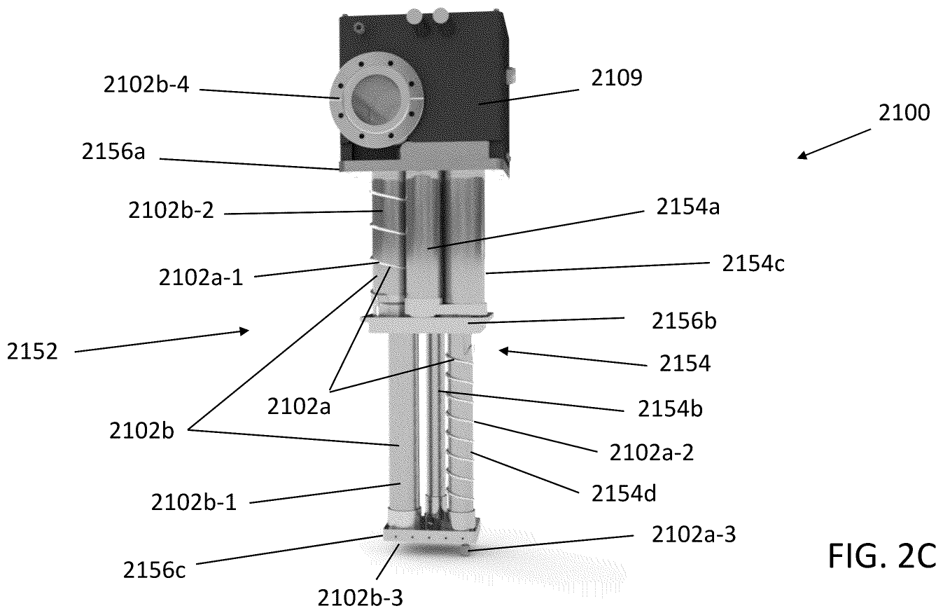

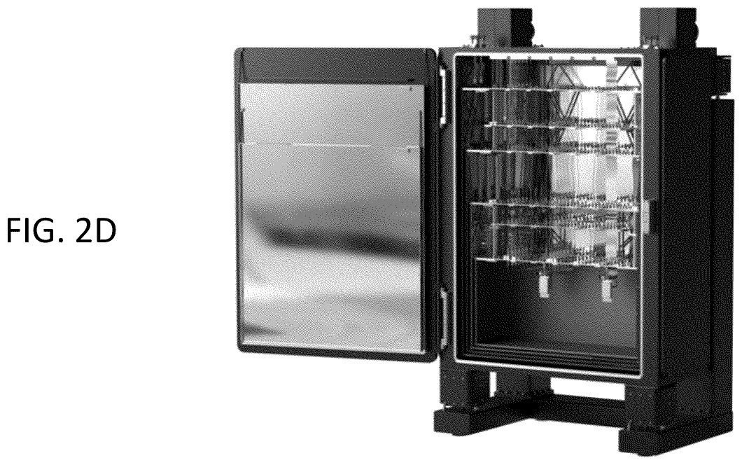

FIG. 1 shows a schematic diagram of a cryogenic system 2000 including a cryocooler 2054 integrated with a dilution refrigerator 2052. In some embodiments, cryocooler 2054 may comprise a pulse tube or another type of cryocooler. FIGS. 2A-2D show illustrative components of a cryogenic system such as cryogenic system 2000, including illustrative components of a cryocooler (such as cryocooler 2054) integrated with illustrative components of a dilution refrigerator (such as dilution refrigerator 2052).

FIG. 2A shows a view of, and FIG. 2B shows a detail view of, a cryogenic system 2100, which is an implementation of cryogenic system 2000 according to various embodiments. Cryogenic system 2100 comprises a cryocooler 2154 integrated with a dilution refrigerator 2152. In the illustrative example of FIGS. 2A-2D, cryocooler 2154 may comprise a pulse tube, but cryogenic systems according to other embodiments may comprise other types of cryocoolers.

As shown in FIG. 2C. the cryogenic system 2100 comprises a cryocooler 2154. Cryocooler 2154 may comprise a pulse tube cryocooler. As illustrated in FIG. 2C, a pulse tube cryocooler may comprise a pulse tube assembly including one or more pulse tubes and one or more pulse tube regenerators. In the illustrated embodiment of FIG. 2C, the cryocooler 2154 comprises a primary pulse tube 2154a, secondary pulse tube 2154b, a primary pulse tube regenerator 2154c, and a secondary pulse tube regenerator 2154d.

Dilution refrigerator 2152 is configured to provide cooling down to cryogenic temperatures. Dilution refrigerator may comprise, among other components described with respect to other figures, a condensing line 2102a, a return 2102b, and one or more flanges 2156a-2156c. According to aspects of the disclosure, dilution refrigerator 2152 of cryogenic system 2100 may be implemented similarly or substantially similarly to dilution refrigerators described herein, such as dilution refrigerator 100 and dilution refrigerator 1200 (described in more detail below), among other embodiments.

The cryogenic system 2100 comprises a condensing line 2102a. As described in further detail below, a ³He/⁴He gas mixture may enter a vacuum chamber of the cryogenic system 2100 through one or more inlets and thereafter may travel through the inner thermal stages of the cryogenic system 2100 through the condensing line 2102a. After performing its cooling function, the ³He/⁴He mixture may return to a pump system through a return 2102b, which may comprise a still pumping line.

The condensing line 2102a may comprise a first condensing line portion 2102a-1 and a second condensing line portion 2102a-2. The condensing line may further comprise an outlet 2102a-3, which may comprise an outlet to a dilution unit for the concentrated helium-3 condensing line. The first condensing line portion 2102a-1 may comprise a concentrated helium-3 condensing line wrap, and may be thermally coupled with the return 2102b, such as by being wrapped around the second sill pumping line portion 2102b-2. The second condensing line portion 2102a-2 may comprise a concentrated helium-3 condensing line wrap, and may be thermally coupled with the cryocooler 2154, such as by being wrapped around the secondary pulse tube regenerator 2154d. Moreover, in some embodiments, the condensing line 2102a may comprise more than two portions. For example, in some embodiments, the condensing line 2102a may comprise a third portion such that the condensing line is configured to heat exchange with the return 2102b (e.g., the still pumping line) in two separate locations, such as both before and after exchanging heat with the cryocooler 2154.

The cryogenic system 2100 may further comprise a return 2102b, which may comprise a still pumping line. The return 2102b may comprise a first return portion 2102b-1 and a second return portion 2102b-2. The return 2102b may be coupled with a return inlet 2102b-3, which may be an inlet from a still (not illustrated in FIG. 2C) into the still pumping line. The coupled still may comprise a still 114 (described in more detail below). The return 2102b may be coupled with a return outlet 2102b-4, which may be an outlet to a pump (not illustrated in FIG. 2C) from the still pumping line. The coupled pump may comprise a pump system 102 (described in more detail below) and/or may comprise a turbomolecular pump.

The dilution refrigerator may comprise one or more flanges 2156a-2156c, which may provide a number of different thermal stages (e.g., thermalization plates) that may be held at decreasing temperature intervals. As described in more detail below a cryogenic system may comprise various thermal stages, such as thermal stages 108a-108f (e.g., thermalization plates), which may be held at decreasing temperature intervals (as merely examples, approximately 50 K, 9-10 K, 3 K, etc.). Each flange of the one or more flanges 2156 may comprise a thermal stage (e.g., thermalization plate). The one or more flanges 2156a-2156c may further be configured to exchange heat between the cryocooler 2154 and the dilution refrigerator 2152 in order to increase the efficiency of the cryogenic system 2100.

Each flange of the one or more flanges of the cryogenic system 2100 may be configured to exchange heat between the cryocooler 2154 and components the dilution refrigerator 2152. The one or more flanges may comprise a first flange 2156a, a second flange 2156b, and a third flange 2156c. The first flange 2156a may comprise a vacuum flange. Second flange 2156b and third flange 2156c may each comprise a thermalization/vacuum flange. Further stages not illustrated in FIG. 2C (but described in further detail below) may be at even lower cryogenic temperatures.

The first flange 2156a may comprise a vacuum flange configured to seal the cryocooler 2154 at a boundary of a vacuum chamber (such as vacuum chamber 106, described in more detail below). In some embodiments, the first flange 2156a may be configured to exchange heat between the cryocooler 2154 and the dilution refrigerator 2152 by thermally coupling two or more of the first condensing line portion 2102a-1, the second return portion 2102b-2, the primary pulse tube 2154a, and the secondary pump tube regenerator 2154c.

As an example, second flange 2156b may comprise a thermalization/vacuum flange at approximately 50K. In some embodiments, the second flange 2156b may be configured to exchange heat between the cryocooler 2154 and the dilution refrigerator 2152 by thermally coupling two or more of the first condensing line portion 2102a-1, the second return portion 2102b-2, the primary pulse tube 2154a, the primary pulse tube regenerator 2154c, the second condensing line portion 2102a-2, the first return portion 2102b-1, the secondary pulse tube 2154b, the secondary pulse tube regenerator 2154d.

As an example, third flange 2156c may comprise a thermalization/vacuum flange at approximately 4K. In some embodiments, the second flange 2156b may be configured to exchange heat between the cryocooler 2154 and the dilution refrigerator 2152 by thermally coupling two or more of the second condensing line portion 2102a-2, the first return portion 2102b-1, the secondary pulse tube 2154b, and the secondary pulse tube regenerator 2154d.

In various embodiments, thermal coupling of components of the cryogenic system (e.g., thermal coupling of any of the one or more flanges 2156a-2156c with any components of the cryocooler 2154 and the dilution refrigerator 2152, including the first condensing line portion 2102a-1, the second return portion 2102b-2, the primary pulse tube 2154a, the primary pulse tube regenerator 2154c, the second condensing line portion 2102a-2, the first return portion 2102b-1, the secondary pulse tube 2154b, the secondary pulse tube regenerator 2154d, or thermal coupling of the condensing line 2102a with the return 2102b) may be provided in any appropriate manner, including using wrapping, brazing, soldering, providing components within gas flow, 3D printing components into walls, or by having conduits confined within the heat conductive blocks (e.g., copper blocks of pulse tube flanges), among other approaches for exchanging heat.

FIG. 2C further shows a housing 2109, which may house a switching system such as switching system 109 (described in more detail below). The housing 2109 may comprise a valve manifold housing. In some embodiments, the housing 2109 may house valves or other components of a turbo charger device, such as turbo charger device 111.

The inventors have recognized that integration of a return (e.g., return 2102b, which may comprise a still pumping line) with other components of a cryogenic system 2100 may enable better thermalization of incoming helium gas.

In some less efficient cryogenic systems, a condensing line 2102a may be thermally coupled with components of a cryocooler 2154 as a technique for cooling helium. As one example of such a less efficient arrangement, an incoming (e.g., condensing) helium-3 line of a dilution unit may be wrapped around a first regenerator in order to cool the helium. However, the inventors have recognized that a drawback of this less efficient arrangement is that wrapping the incoming helium-3 line around the first regenerator robs cooling power from the cryogenic system, for example, by expending cooling power to cool helium instead of system wiring.

Accordingly, the inventors have recognized that components of a cryocooler 2154 may be thermally coupled with a return 2102b, allowing a condensing line 2102a to be thermally coupled with the return 2102b (rather than directly thermally coupled with the cryocooler, e.g., the regenerator). By thermally coupling the condensing line 2102a with the return 2102b, the cryogenic system 2100 is able to utilize cooling power from extremely cold gas (e.g., around 700 mK) rather than rejecting it to room temperature. One specific configuration according to the disclosure involves integrating a primary pulse tube with a still pumping line of the dilution unit (such as by using a flanger), and wrapping the incoming condensing helium-3 line around the still pumping line. This improved arrangement also allows for simplified integration of regenerating and light-blocking baffles into a cryogenic system. These integration and associated features provide improved cooling performance and overall efficiency of a cryogenic system.

The inventors have recognized further advantages of the integrated cryocoolers and dilution refrigerator described herein. As another example, by integrating a still pumping line and a pulse tube, a helium-3 condensing line may easily be transitioned from the still pumping line to a regenerator line below a primary stage of a pulse tube (which may be around 40 Kelvin) to the secondary stage regenerator line without introducing excess helium-3 volume to the system. In various embodiments, a dilution refrigerator condensing line may be integrated with the pulse tube assembly and still pumping line to allow for heat exchange in any appropriate manner, including wrapping, brazing, soldering sticking the tube inside the gas flow, 3D printing the tube into a wall, or by having conduits confined within the heat conductive blocks (e.g., copper blocks of pulse tube flanges), among other approaches for exchanging heat.

According to conventional approaches, there may be an entirely separate pulse tube and dilution unit, which is space intensive, resulting in a larger cryogenic system footprint. Operable portions of a pulse tube may require significant space from room temperature to approximately 3K. A dilution unit also requires significant space from below 3 Kelvin until the base temperature with limited requirements from 3K to room temperature. The inventors have recognized that integrating the still pumping line into the pulse tube assembly provides a significantly smaller footprint of a cryogenic system. Providing a smaller footprint of a cryogenic system is advantageous for a variety of reasons, including because the smaller footprint reduces excess radiative heat loads and thermal mass of the cryogenic system and also preserves additional space for non-operative elements of the cryogenic system, including wires, electronics, experiments, or workloads.

As such, in cryogenic systems, integrating a dilution refrigerator with a pulse tube or other 4K cryogenic system, for example using integration of a still pumping line into a pulse tube assembly provides several significant benefits over conventional systems, including improved cooling performance, improved energy efficiency, and a smaller footprint, among other valuable benefits in the field of cryogenics.

According to various embodiments, the thermally coupled cryocooler and dilution refrigerator may provide improved performance. For example, cryogenic systems incorporating the thermally coupled cryocooler and dilution refrigerator may provide a base temperature under 10 mK, greater than 130 L of sample volume, at least 600 L of total internal volume, and greater than 4,000 cm² of area on a mixing chamber plate, while providing a cooling power of 1000 μW at 100 mK. Furthermore, cryogenic systems described herein may have a compact system footprint, providing double cooling power and quadruple experimental volume with only a 50% increased footprint compared to other systems. Such system performance may be enabled by the efficient thermalization and attenuation layout described herein, as well as the improved integrated pulse tubes provided by the disclosure. The thermally coupled cryocooler and dilution refrigerator may further allow cryogenic systems to have a form factor that dramatically reduces footprint, thermal mass, and radiative heat loads. Compared with conventional round dilution refrigerators, which may dedicate at least 10-25% of plate area to user wiring, cryogenic systems described herein may provide at least 50% of plate area dedicated to user wiring, which may reduce excess heat loads. Such a large, dedicated area provides a more efficient system that supports running multiple experiments simultaneously. Furthermore, cryogenic systems may include parallel-loading wiring inserts make that allow large samples to be wired outside the cryogenic system and loaded as a single assembly.

In some alternative or additional embodiments, temperatures referred to in embodiments described herein may be substituted for approximately the temperatures referred to. For example, approximately 4.2 Kelvin may in some alternative or additional embodiments be used where “4.2 Kelvin” is referred to.

### II. Closed-Cycle Dilution Refrigerator

Dilution refrigerators are cryogenic devices that rely on the heat of mixing of the ³He and ⁴He isotopes to provide cooling down to temperatures between approximately 2 mK and 1 K. Classic dilution refrigerators, or “wet” dilution refrigerators, precool the ³He/⁴He mixture using liquid nitrogen and ⁴He baths before further cooling of the ³He/⁴He mixture below 4 K. Modern dilution refrigerators, or “dry” dilution refrigerators, precool the ³He/⁴He mixture using devices such as a cryocooler rather than cryogenic liquid baths.

Dilution refrigerators are cryogenic devices that can provide cooling down to temperatures between approximately 2 mK and 1 K and are used in a variety of applications requiring these extremely low temperatures. For example, dilution refrigerators can be used to support quantum computing (e.g., superconducting quantum computing technologies and qubits) and low-temperature condensed matter physics research, among other applications.

As described above, dilution refrigerators rely on the heat of mixing of ³He and ⁴He isotopes to provide cooling. When cooled below approximately 870 mK, a ³He/⁴He mixture undergoes spontaneous phase separation to form a ³He-rich phase (the “concentrated” phase) and a ³He-poor phase (the “dilute” phase). These two phases are maintained in equilibrium in a mixing chamber, the coldest part of the dilution refrigerator, and are separated by a phase boundary. In the mixing chamber, the ³He is diluted as it moves from the concentrated phase through the phase boundary into the dilute phase, and the heat necessary for this endothermic dilution process provides the cooling power of the dilution refrigerator.

However, conventional dilution refrigerators can suffer from a multitude of drawbacks and failure points. For example, wet dilution refrigerators require significant amounts of liquid cryogens, which are costly to maintain and supply. As another example, dry dilution refrigerators can be subject to unwanted mechanical vibrations introduced by the cryocooler system and/or may draw large amounts of energy to power the cryocooler.

Conventional dilution refrigerators also typically occupy a large footprint, which may be prohibitive for applications requiring multiple dilution refrigerators. For example, a single conventional dry dilution refrigerator typically requires approximately 300 square feet and ceiling heights between 12 and 14 feet. This space is occupied not only by the dilution refrigerator itself but is also required to support any auxiliary systems such as pumps, compressors, water cooling systems and/or cryocooler systems.

The inventors have recognized and appreciated that, for quantum computing and other quantum technologies to be easily scalable, the quantum technology industry needs reliable, easy-to-use, easy-to-maintain, and compact dilution refrigerators. Accordingly, the inventors have developed dilution refrigerators and distributed cooling systems that can be integrated with commercially available server rack infrastructure (e.g., 19-inch server racks). Additionally, the inventors have developed a number of features, described herein, to ease maintenance of the dilution refrigerators, speed cooling of the dilution refrigerators without the use of mechanical pumps, and to reduce the transmission of mechanical vibrations to the experimental volume of the dilution refrigerator.

Some embodiments are directed to a dilution refrigerator comprising: a plurality of thermalization plates configured to be cooled to a plurality of temperatures, wherein: a first thermalization plate of the plurality of thermalization plates comprises an integrated heat exchanger, the integrated heat exchanger comprises channels formed in the first thermalization plate, and the channels are configured to allow helium to flow through the first thermalization plate during operation of the dilution refrigerator.

In some embodiments, the integrated heat exchanger is formed by additive manufacturing.

In some embodiments, the first thermalization plate further comprises a detachable portion, the detachable portion comprising the integrated heat exchanger.

In some embodiments, the dilution refrigerator further comprises an interchangeable dilution insert detachably coupled to the detachable portion of the first thermalization plate.

In some embodiments, the dilution insert is detachably coupled to: a condensing line of the dilution refrigerator; and three thermalization plates of the plurality of thermalization plates.

In some embodiments, the dilution insert comprises a still configured to perform cooling by distilling ³He vapor from a mixture of ³He and ⁴He.

In some embodiments, the dilution refrigerator further comprises an experimental volume thermally coupled to a coldest thermalization plate of the plurality of thermalization plates; a still coupled to a second thermalization plate warmer than the coldest thermalization plate, the still being configured to perform cooling by distilling ³He vapor from a mixture of ³He and ⁴He; and a continuous heat exchanger disposed between the second thermalization plate and the coldest thermalization plate.

In some embodiments, the dilution refrigerator further comprises at least one heat exchanger thermally coupled to a thermalization plate of the plurality of thermalization plates, wherein the at least one heat exchanger comprises a nanomaterial.

In some embodiments, the nanomaterial comprises at least one or nanowires, nanofoams, nanopellets, and/or nanotubes.

In some embodiments, the nanomaterial comprises nanowires comprising one or more of copper nanowires, silver nanowires, gold nanowires, platinum nanowires, polymer nanowires, carbon nanowires, and/or carbon fiber nanowires.

In some embodiments, the at least one heat exchanger comprises one of a discrete heat exchanger and/or a heat exchanger disposed in a mixing chamber of the dilution refrigerator.

In some embodiments, the dilution refrigerator further comprises: a condensing line configured to transport helium to a coldest thermalization plate of the plurality of thermalization plates; a still disposed along the condensing line before the coldest thermalization plate; a heat exchanger disposed along the condensing line between the still and the coldest thermalization plate; and a heat exchange line configured to transfer a return helium mixture from the heat exchanger to the still and to decrease a temperature of a helium mixture in the condensing line at a location above the still.

In some embodiments, the dilution refrigerator further comprises a Joule-Thomson expander disposed along the condensing line before the still, wherein: the heat exchange line is configured to decrease the temperature of the helium mixture in the condensing line at a location before the Joule-Thomson expander.

In some embodiments, the dilution refrigerator further comprises: a condensing line configured to transport helium to a coldest thermalization plate of the plurality of thermalization plates; and a high-surface area material disposed along the condensing line and configured to cause the transported helium to adsorb to the high-surface area material during a cooldown cycle of the dilution refrigerator.

In some embodiments, a first end of the high-surface area material is switchably thermally coupled to a warmer thermalization plate of the plurality of thermalization plates by a first heat switch, and a second end opposite the first end of the high-surface area material is switchably thermally coupled to a colder thermalization plate of the plurality of thermalization plates by a second heat switch.

In some embodiments, the dilution refrigerator further comprises at least one heater thermally coupled to the high-surface area material and configured to cause, by heating the high-surface area material, the adsorbed helium to release from the high-surface area material and to be cooled by moving between a warmer thermalization plate of the plurality of thermalization plates to a colder thermalization plate of the plurality of thermalization plates.

In some embodiments, the dilution refrigerator further comprises: a first valve disposed along the condensing line between the warmer thermalization plate and the high-surface area material; and a second valve disposed along the condensing line between the high-surface area material and the colder thermalization plate, wherein: the first valve and the second valve are configured to, when the first valve is closed and the second valve is opened, cause helium adsorbed onto the high-surface area material to be transported from the warmer thermalization plate to the colder thermalization plate.

In some embodiments, the high-surface area material comprises one of activated charcoal or a metal powder.

In some embodiments, the dilution refrigerator further comprises: a condensing line configured to transport helium from a helium inlet to a coldest thermalization plate of the plurality of thermalization plates; a first helium filter disposed along the condensing line; a second helium filter disposed in parallel with the first helium filter along the condensing line; and at least one valve configured to switch a flow of helium along the condensing line between the first helium filter and the second helium filter.

In some embodiments, the first helium filter and/or the second helium filter comprises a charcoal trap.

In some embodiments, the dilution refrigerator further comprises: a first counterflow heat exchanger disposed between the first helium filter and the helium inlet; and a second counterflow heat exchanger disposed between the second helium filter and the helium inlet.

In some embodiments, the dilution refrigerator further comprises: a condensing line configured to transport helium to a coldest thermalization plate of the plurality of thermalization plates; a Joule-Thomson expander disposed along the condensing line; and a bypass disposed in parallel with the Joule-Thomson expander along the condensing line, the bypass configured to allow the transported helium to bypass the Joule-Thomson expander when the transported helium has a temperature above a threshold value and below 300 K.

In some embodiments, the bypass comprises a material configured to allow the transported helium to diffuse through the material when the transported helium has a temperature above the threshold value and below 300K. In some embodiments, the material comprises a polymer.

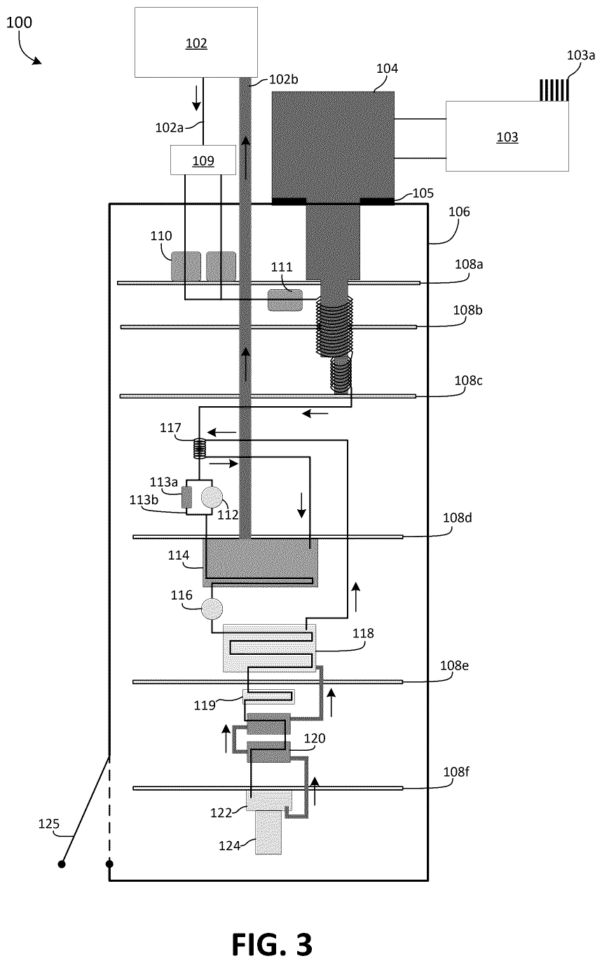

FIG. 3 is a schematic diagram of a dry, closed-cycle dilution refrigerator 100, in accordance with some embodiments described herein. In some embodiments, the dilution refrigerator 100 includes an outer vacuum chamber 106 at room temperature (e.g., approximately 300K) and a number of thermal stages 108a-108f (e.g., thermalization plates) held at decreasing temperature intervals (e.g., approximately 50 K, 9-10 K, 3 K, etc.). For example, the first thermal stage 108a may be at approximately 50 K, the second thermal stage 108b may be at approximately 9-10 K, the third thermal stage 108c may be at approximately 3-4 K, the fourth thermal stage 108d may be at approximately 800 mK, the fifth thermal stage 108e may be at approximately 100 mK, and the sixth thermal stage 108f may be at approximately 10 mK.

In some embodiments, the dilution refrigerator 100 may include a pump system 102 that pressurizes a ³He/⁴He gas mixture (e.g., to a pressure at or near 1 bar). The ³He/⁴He gas mixture may enter the outer vacuum chamber 106 through one or more inlets and thereafter may travel through the inner thermal stages 108a-108f through the condensing line 102a. After performing its cooling function, the ³He/⁴He mixture may return to the pump system through the return 102b.

In some embodiments, the ³He/⁴He mixture may be purified prior to traveling along the condensing line 102a through the thermal stages 108a-108f. Contaminants in the helium flowing through the dilution refrigerator can clog certain components (e.g., the Joule-Thomson expander or capillaries in the heat exchangers) and lead to performance degradation or system failure. Conventionally, to reduce the risk of contaminants making their way into the system, helium is first passed through an external ‘cleaning trap’ filled with activated charcoal before entering the dilution unit of the dilution refrigerator. These external traps must be surrounded by liquid nitrogen and refilled at frequent intervals, which requires user maintenance and interaction.

The inventors have recognized and appreciated that passive helium filters, without the need for refilling of liquid nitrogen, can improve the user experience and reduce maintenance frequency of a dilution refrigeration system. Accordingly, in some embodiments, the dilution refrigerator 100 includes one or more helium cleaning devices 110. In some embodiments, where the dilution refrigerator 100 includes two or more helium cleaning devices 110, the dilution refrigerator 100 may further include a switching system 109 configured to direct the flow of the helium to a single helium cleaning device 110.

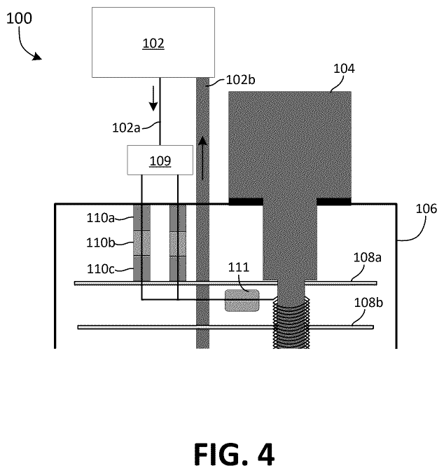

FIG. 4 shows a schematic diagram of helium cleaning devices 110, in accordance with some embodiments described herein. The helium cleaning devices 110 may be coupled to the pump system 102 by a switching system 109 that is disposed outside of the outer vacuum chamber 106. The switching system 109 may include one or more helium-compatible valves. The switching system 109 may be configured to switch helium flow between each of the helium cleaning devices 110. In this manner, one helium cleaning device 110 may be used for actively filtering helium while the dilution refrigerator is in operation while the other helium cleaning device may be cleaned (e.g., by heating and pumping out of impurities), enabling indefinite periods of operation of the dilution refrigerator 100.

In some embodiments, the helium cleaning devices 110 include a counter flow heat exchanger 110a, a trap 110b, and a weak thermal contact 110c (e.g., a gas gap heat exchanger, a low thermal conductivity attachment, etc.). The counter flow heat exchanger 110a and the weak thermal contact 110c may reduce the thermal load of the helium cleaning devices 110 on the dilution refrigerator 100 and may eliminate the use of cryogenic valves in the helium cleaning devices 110. The trap 110b may include, for example, a high surface area material (e.g., charcoal, activated charcoal, and/or a metal powder) configured to capture non-helium impurities in the dilution refrigerator 100.

Returning to FIG. 3, in some embodiments, the dilution refrigerator 100 may include a cooldown turbo charger device 111. Dry dilution refrigerators conventionally use an auxiliary compressor to enable the flow of warm helium, which initially has a high impedance and resists such movement. The extra pressure from the auxiliary compressor also pressurizes the helium, causing the helium to reach a pressure that starts isenthalpic expansion and cooling at a higher temperature. These auxiliary mechanical compressor pumps are costly, prone to reliability issues, frequently leak, and can cause performance degradation over time. The inventors have recognized and appreciated that, alternatively, the helium may be pulsed through the dilution refrigerator during cooldown without the use of an auxiliary mechanical pump, enabling a faster and more efficient cooldown process.

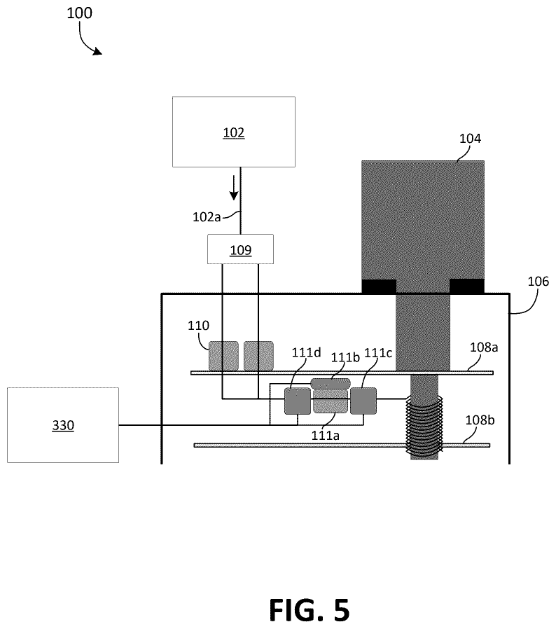

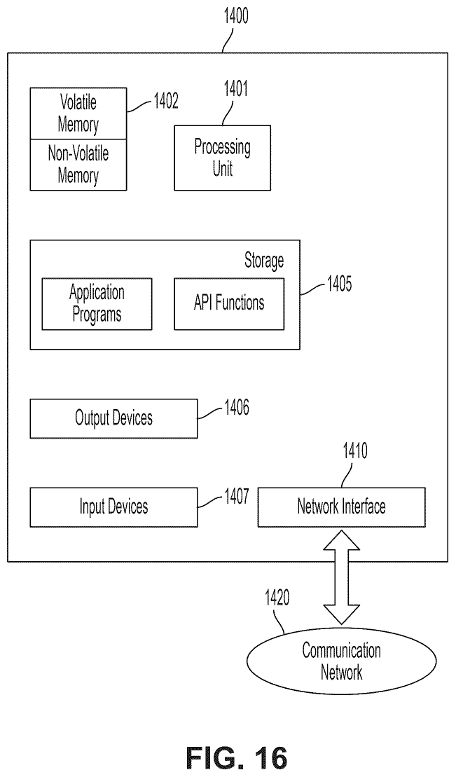

FIG. 5 shows a schematic diagram of a cooldown turbo charger device 111, in accordance with some embodiments described herein. The cooldown turbo charger device 111 may include a volume of a high surface area material 111a, a heater 111b, a first valve 111c, and a second valve 111d. The first and second valves 111c, 111d may be, for example, cold valves located inside the vacuum chamber 106. As another example, the first and second valves 111c, 111d may be room temperature valves located outside of the vacuum chamber 106. In some embodiments, the heater 111b and the first and second valves 111c, 111d may be communicatively coupled to a controller 330. The controller 330 may be, for example, a computer as described in connection with FIG. 16 herein.

In some embodiments, the cooldown turbo charger device 111 may be thermally coupled to a thermal stage (e.g., to a thermalization plate). In the example of FIG. 5, the high surface area material 111a is thermally coupled to the second thermal stage 108b, though it should be appreciated that the high surface area material 111a could be thermally coupled to another thermal stage in some embodiments (e.g., first thermal stage 108a).

Alternatively, in some embodiments, the cooldown turbo charger device 111 may be thermally coupled to multiple thermal stages (e.g., across two or more thermal stages 108a-108f). In such embodiments, the sequential heating and cooling of the high surface area material 111a may be mediated by heat switches. For example, the cooldown turbo charger device 111 may be switchably thermally coupled between a warmer thermal stage and a colder thermal stage such that the cooldown turbo charger device 111 may be thermally coupled to either the warmer thermal stage or the colder thermal stage. When the cooldown turbo charger device 111 is thermally coupled to the warmer thermal stage, the high surface area material 111a may release any adsorbed helium. When the cooldown turbo charger device 111 is thermally coupled to the colder thermal stage, helium may begin adsorbing to the high surface area material 111a. In this manner, a sequential flushing of helium through the condensing line 102a may be implemented.

In some embodiments, the high surface area material 111a may comprise a material with a porous and/or textured surface such that helium adsorbs to the high surface area material 111a during the cooldown process. For example, the high surface area material 111a may comprise activated charcoal, a metal powder (e.g., a copper or silver powder), and/or a material composite formed of nanostructures (e.g., nanowires, nanoparticles, etc.).

In some embodiments, the cooldown turbo charger device 111 may be operated using a sequential opening and closing of the valves 111c, 111d in concert with operation of the heater 111b. For example, to cause helium to adsorb the high surface area material 111a, the first valve 111c may be closed to prevent helium from flowing to the lower stages of the dilution refrigerator 100 and the second valve 111d may be opened to allow helium to reach the high surface area material 111a. The first valve 111c may be closed and the second valve 111d may be opened by the controller 330 in response to a measured pressure or temperature or in response to a timing signal generated by controller 330.

In some embodiments, after sufficient helium has adsorbed onto the high surface area material 111a, the second valve 111d may be closed and the first valve 111c may be opened. The first and second valves 111c, 111d may be opened and/or closed in response to measured temperatures or pressures and/or in response to a timing signal generated by controller 330.

In some embodiments, when the second valve 111d is closed and the first valve 111c is opened, the heater 111b may also be caused, at a same or similar time, to heat the high surface area material 111a in response to a signal generated by controller 330. For example, the heater 111b may be a resistive heater that is caused to heat the high surface area material 111a by a flow of current through the heater 111b. In response to the heat from the heater 111b, the helium adsorbed to the high surface area material 111a may act as a reserve that is then released from the high surface area material 111a. This release of the adsorbed helium may increase the pressure in the remainder of the condensing line 102a, and the increased pressure may enable the start of isenthalpic expansion to speed cooling of the dilution refrigerator 100.

In some embodiments, once the helium has been released from the high surface area material 111a, the first valve 111c may be closed, the second valve 111d may be opened, and the heater 111b may be turned off by the controller 330, allowing new helium to adsorb to the high surface area material 111a. The controller 330 may be configured to periodically (e.g., at regular time intervals, at irregular time intervals, at time intervals determined by the temperature of the experimental volume, at time intervals determined by the pressure of the experimental volume) open and/or close the valves 111c, 111d and to operate the heater 111b to flush the helium intake path. In some embodiments, the controller 330 may be configured to “pulse” the helium from the high surface area material 111a through the condensing line 102a, causing the dilution refrigerator to be cooled.

Returning to FIG. 3, during operation of the dilution refrigerator, the ³He/⁴He mixture may be progressively cooled as it travels along the condensing line 102a from the first thermal stage 108a to the mixing chamber 122. At the first thermal stage, the helium may be initially cooled to approximately 50 K. After exiting the cooldown turbo charger device, the ³He/⁴He mixture may next be cooled by a cryocooler 104. A portion of the cryocooler 104 may be disposed partially outside of the outer vacuum chamber 106, in some embodiments. The cryocooler 104 may be vibrationally isolated from outer vacuum chamber 106 by a vibration isolation stage 105, which may comprise padding and/or any other suitable vibration isolation techniques.

In some embodiments, the cryocooler 104 may be coupled to a cryocooler support 103. The cryocooler support 103 may be, for example, a compressor and/or compression system, in some embodiments. The cryocooler support 103 may include cooling members 103a, in some embodiments, configured to provide air-cooling to the dilution refrigerator 100. The cooling members 103a may be, as a non-limiting example, cooling fins, fans, and/or heat pipes configured to remove waste heat generated by the cryocooler support 103 and/or the cryocooler 104.

The cooling members 103a are in contrast to conventional closed-cycle dilution refrigerators, which typically rely on water-cooling to remove waste heat generated by the integrated cryocooler. Water-cooling of the cryocooler, however, requires installing a large and/or expensive water-cooling system in conjunction with the dilution refrigerator. Additionally, such water-cooling systems are not typically integrated with commercial computing facilities, which typically rely on air-cooling as it is less expensive and does not present hazards (e.g., leaking coolant, flooding, etc.) to the electronic equipment. The inventors have accordingly recognized that using air-cooling to remove heat from the cryocooler of the dilution refrigerator may reduce the costs of manufacturing dilution refrigerators and enable their use in commercial computing facilities.

In some embodiments, the dilution refrigerator 100 may be disposed above a plenum (not pictured) disposed under a floor supporting the dilution refrigerator. The plenum may supply the cooling members 103a with air flow to provide air-cooling. In some embodiments, the cooling members 103a may include inlets and/or louvers configured to draw in air from the plenum. Alternatively or additionally, in some embodiments, the dilution refrigerator 100 may be disposed in a facility including ductwork and/or heat pipes (not pictured) arranged to remove heat from the cooling members 103a, the cryocooler support 103, and/or the cryocooler 104 and to minimize vibrations experienced by the dilution refrigerator 100.

In some embodiments, the ³He/⁴He mixture may be cooled by the cryocooler 104 in two steps. The condensing line 102a may be wound around two portions of the cryocooler 104 to effect heat exchange between the ³He/⁴He mixture in the condensing line 102a and the cryocooler 104. In a first step, the ³He/⁴He mixture may be cooled to approximately 10 K by the cryocooler 104. In a second step, the ³He/⁴He mixture may be cooled to approximately 3-4 K by the cryocooler 104.

In some embodiments, after being cooled by the cryocooler 104, the ³He/⁴He mixture may pass through the third thermal stage 108c. The third thermal stage 108c may be thermally coupled but mechanically decoupled from cryocooler 104, in some embodiments, in order to provide vibration isolation to the later thermal stages 108d-108f. As a non-limiting example, in some embodiments, third thermal stage 108c may be mechanically decoupled from the cryocooler by a copper braid, heat strap, or other hanging component configured to maintain thermal coupling between the third thermal stage 108c and the cryocooler 104.

In some embodiments, after passing through the third thermal stage 108c, the ³He/⁴He mixture may enter a primary impedance stage 112. The primary impedance stage 112 may be a Joule-Thomson expander configured to reduce the temperature and/or pressure of the ³He/⁴He mixture. For example, in some embodiments, the ³He/⁴He mixture may be at approximately 3-5 K before entering the primary impedance stage 112 and may be at approximately 1 K after exiting the primary impedance stage 112.

In some embodiments, the primary impedance stage 112 may be a Joule-Thomson expander formed from a fiber optic cable. Conventionally, Joule-Thomson expanders may be formed as metal tubes that are manufactured by pulling. However, such metal Joule-Thomson expanders may suffer from irregularities and/or may have a larger diameter that reduces the cooling power of the device. A hollow-core fiber optic cable may reliably and reproducibly provide the narrow opening needed for a Joule-Thomson expander.

In some embodiments, the dilution refrigerator 100 may include a bypass device 113a configured to increase the speed of cooldown of the dilution refrigerator 100. For example, during the initial cooldown of a dilution refrigerator, the helium flow rate may be low due to the large impedance of Joule-Thomson expanders in the dilution refrigerator and the warm, low density, and viscous circulating helium. This reduced helium flow rate reduces the rate of cooling of the lower portions of the refrigerator. To combat this effect, conventionally, a needle valve may be incorporated at a location on the condensing line above the Joule-Thomson expander to reduce the impedance of the initially-warm helium gas. However, the needle valve includes mechanical components that may fail over time. The inventors have recognized and appreciated that the helium flow rate may be improved without reliance on a mechanical component such as a needle valve.

In some embodiments, the bypass device 113a may be disposed along the condensing line 102a in parallel with the primary impedance stage 112 and on a bypass line 113b that bypasses the primary impedance stage 112 (e.g., allowing the ³He/⁴He mixture to flow around the primary impedance stage 112). The bypass device 113a may include a sheet of vacuum-compatible material configured to allow helium to diffuse through the material at temperatures above a threshold temperature value. For example, the bypass device 113a may allow the ³He/⁴He mixture to diffuse through the bypass device 113a at temperatures in a range from approximately 40 K to 300 K, in a range from 50 K to 300 K, in a range from 80 K to 300 K, in a range from 100 K to 300 K, in a range from 150 K, or in any range within those ranges. In some embodiments, the bypass device 113a may include a sheet of a vacuum-compatible polymer material. For example, the bypass device 113a may be formed of a sheet of Kapton, PEEK, and/or mylar, as some non-limiting examples. The bypass device 113a therefore allows for the high impedance of the primary impedance stage 112 to be circumvented when the ³He/⁴He mixture is warm, thereby increasing the helium flow rate and rate of cooling of the dilution refrigerator 100. When the dilution refrigerator 100 has cooled sufficiently (e.g., to below the threshold temperature value), the ³He/⁴He mixture will no longer diffuse through the bypass device 113a and instead will flow through the primary impedance stage 112.

In some embodiments, after exiting the primary impedance stage 112 or the bypass device 113a, the ³He/⁴He mixture then travels past the fourth thermal stage 108d and into the still 114. The still 114 may contain a different mixture of liquid ³He/⁴He that cools the incoming ³He/⁴He mixture as it passes through the condensing line 102a running through the still 114. In some embodiments, the ³He/⁴He mixture in the condensing line may be cooled to approximately 400-900 mK by the still 114.

In some embodiments, the still 114 may include a membrane configured to use second sound to improve ³He evaporation within the still. Second sound is a superfluid phenomenon present in superfluid helium and may be produced, for example, when a porous membrane is oscillated or a heated wire is cycled within a bath of superfluid helium. The two-fluid model specifies that the superfluid helium in the mixture moves through the membrane while non-superfluid components of the helium bath cannot pass through the porous membrane as easily. In superfluid helium, this creates an enthalpy or temperature wave. Analogously in helium mixtures, the non-superfluid ³He may be preferentially pushed by the oscillating membrane while the superfluid ⁴He remains relatively stationary. The inventors have recognized and appreciated that this second sound phenomenon can be implemented within the still 114 to increase the ³He evaporation rate at a lower temperature and to reduce a concentration of ⁴He in the vapor above the liquid helium mixture in the still.

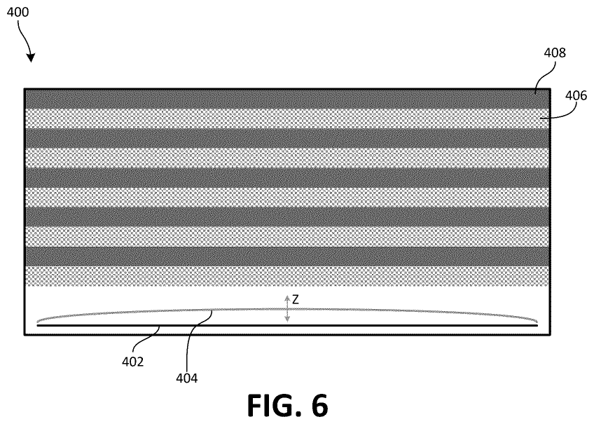

FIG. 6 is a schematic diagram of a still 400 including a device to separate ³He and ⁴He using second sound effects, in accordance with some embodiments described herein. The still 400 may be implemented as still 114 of dilution refrigerator 100, in some embodiments. The still 400 may include a stationary surface 402 and a porous, movable membrane 404. The porous membrane 404 may be oscillated along the Z direction to create standing concentration waves of ³He within the still so that there are regions 406 of lower ³He concentration and regions 408 of high ³He concentration. The standing wave may be tuned such that regions 408 of high ³He concentration are disposed adjacent an outlet of the still, thereby allowing for improved ³He purification.

Returning to FIG. 3, in some embodiments, after exiting the still 114, the ³He/⁴He mixture may flow through the condensing line 102a to a secondary impedance stage 116. The secondary impedance stage 116 may be configured to ensure that only liquid ³He/⁴He proceeds further downstream in the dilution refrigerator 100 and that gas cavitation in the still 114 does not occur (e.g., by maintaining a threshold pressure in the still 114). The secondary impedance stage 116 may therefore reduce downstream cooling loads due to a latent heat of gaseous ³He/⁴He.

In some embodiments, after exiting the secondary impedance stage 116, the ³He/⁴He mixture may then flow into a first heat exchanger 118. The first heat exchanger 118 may be a continuous heat exchanger. For example, the first heat exchanger 118 may be a counterflow (e.g., a tube-tube heat exchanger), a cross-counterflow, and/or coflow heat exchanger. At the exit of the first heat exchanger 118, the ³He/⁴He mixture in the condensing line 102a may be cooled to a temperature of approximately 20 mK.

In conventional closed-cycle dilution refrigerators, prior to entering the still, the ³He/⁴He mixture in the condensing line typically must pass through a first impedance stage. This first impedance stage typically acts as an independent refrigeration stage, known as a Joule-Thomson refrigerator, where the ³He/⁴He mixture is cooled by isenthalpic expansion. In order to control the cooling power of the ³He/He mixture expansion, the pressure of the ³He/⁴He mixture in the condensing line is typically raised by an external compressor.

The inventors have recognized and appreciated that reducing the temperature of the ³He/⁴He mixture prior to entering the first impedance stage can achieve the same cooling effect (e.g., the ³He/⁴He mixture can reach the same base temperature after passing through the first impedance stage) while using a lower pressure differential. Such a configuration can improve the efficiency of the dilution refrigerator and reduce or eliminate the need to pressurize the ³He/⁴He mixture before the first impedance stage. Further, the inventors have recognized that the heat removed from the ³He/⁴He mixture prior to the first impedance stage can be returned to the still, thereby eliminating or reducing the need for a supplemental heater within the still to raise the vapor pressure, and enabling evaporation, of the different ³He/⁴He mixture present in the still.

Accordingly, in some embodiments, the dilution refrigerator 100 may include a heat exchange line 117 configured to transfer heat from the incoming condensing line 102a to a return helium mixture being transported from the first heat exchanger 118 to the still 114. The heat exchange line 117 may cool the condensing line 102a at a location above the primary impedance stage 112. The heat exchange line 117 then cools the ³He/⁴He mixture in the condensing line 102a prior to entering the primary impedance stage 112. Thereafter, the warmed mixture in the heat exchange line 117 is transported to the still 114.

Cooling the incoming ³He/⁴He mixture before it enters the primary impedance stage 112 causes the primary impedance stage 112 to output a ³He/⁴He mixture with a higher proportion of ³He in the liquid state rather than in the vapor state. Thus, the primary impedance stage 112 can be made more efficient by including the additional heat exchange line 117. Additionally, this improved efficiency eliminates or mitigates the need for supplemental pressure (e.g., an external compressor) and may lower the flow impedance of the circulating helium mixture. This is particularly useful in reducing the complexity and size of smaller dilution refrigerators that include smaller (i.e., less powerful) pulse tubes or other cryocoolers.

In some embodiments, after exiting the first heat exchanger 118, the ³He/⁴He mixture passes through the fifth thermal stage 108e and enters continuous heat exchanger 119. The continuous heat exchanger 119 may be a counterflow (e.g., a tube-tube heat exchanger), a cross-counterflow, and/or coflow heat exchanger. The continuous heat exchanger 119 is disposed below the fifth thermal stage 108e. The fifth thermal stage 108e may be an intermediate cold plate (ICP) configured to be cooled to a temperature of approximately 100-200 mK. While continuous heat exchangers are typically more efficient than discrete heat exchangers, they become less efficient below a temperature of approximately 80 mK. However, adding continuous heat exchanger 119 below the fifth thermal stage 108e may enable the fifth thermal stage 108e to operate with more cooling power during the process of cooling down the dilution refrigerator.

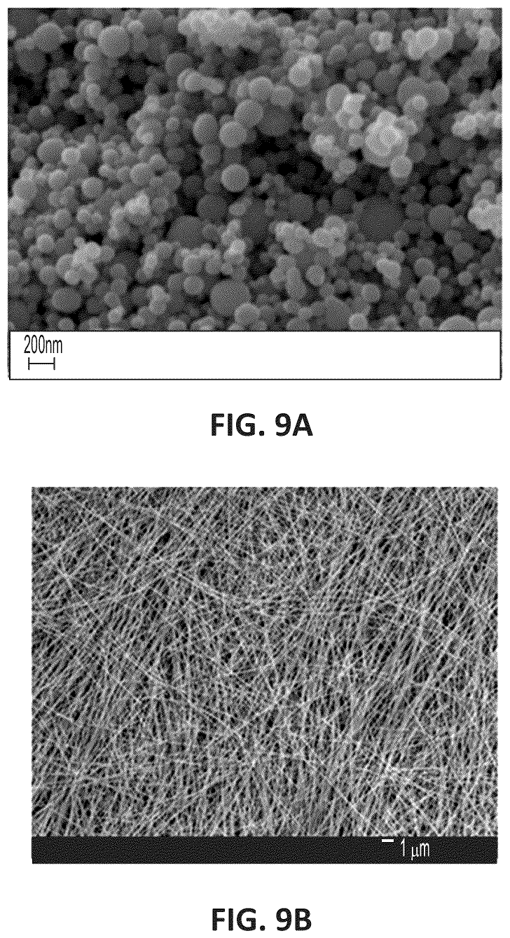

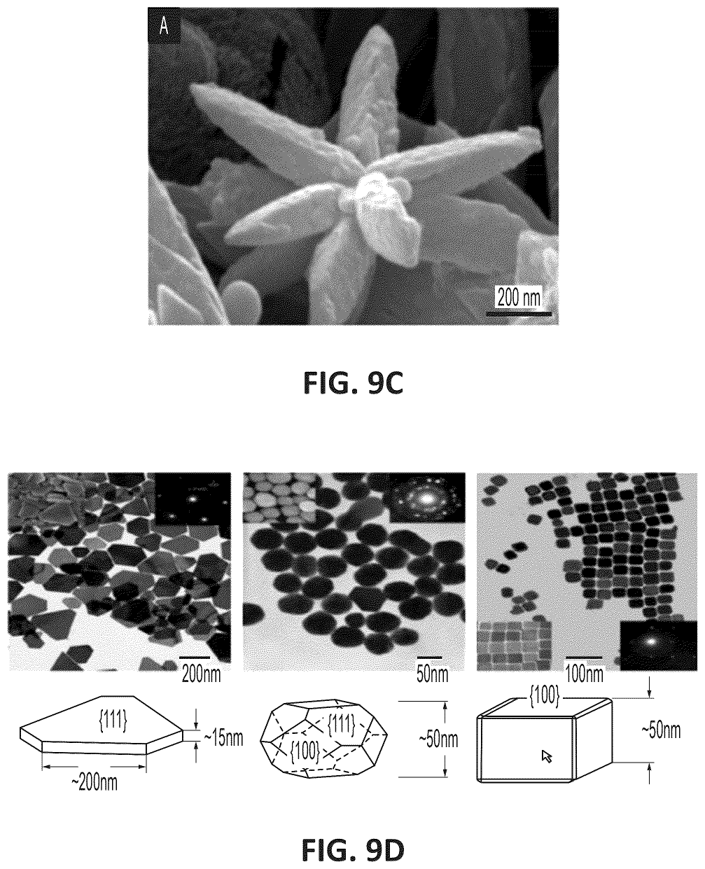

In some embodiments, after exiting the continuous heat exchanger 119, the ³He/⁴He mixture enters discrete heat exchangers 120. The discrete heat exchangers 120 may be formed of sintered nanoparticles, in some embodiments. Alternatively or additionally, in some embodiments the discrete heat exchangers 120 may be formed of sintered nanowires, as described herein in connection with FIGS. 9A-9D herein. The discrete heat exchangers 120 may be configured to further cool the ³He/⁴He mixture to a temperature below approximately 10-20 mK.

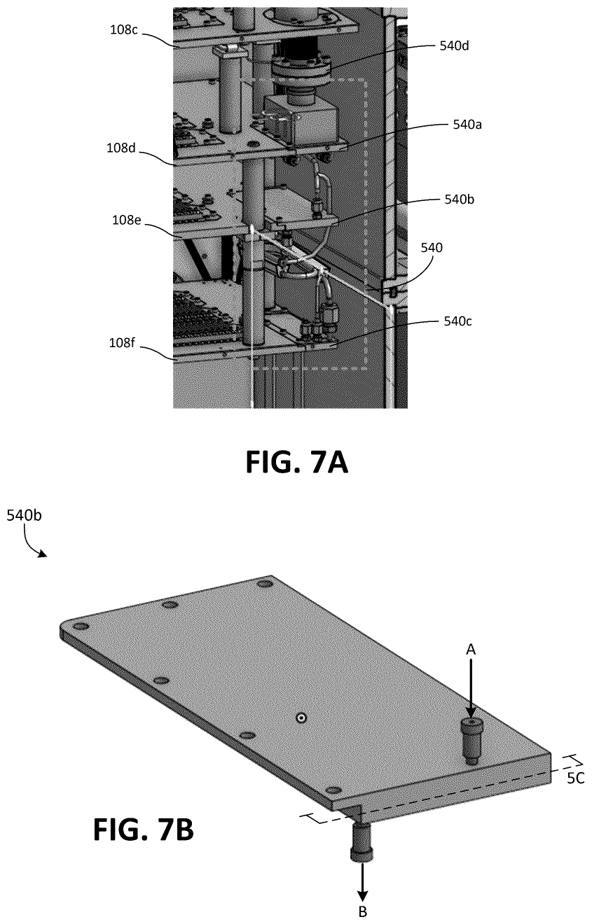

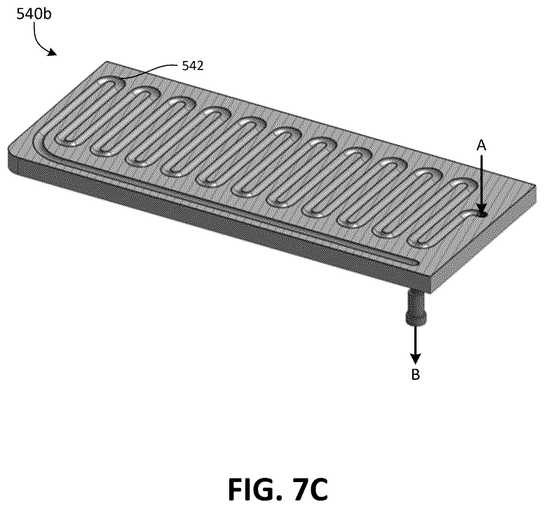

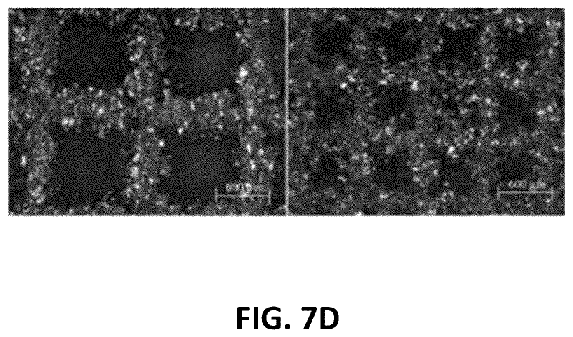

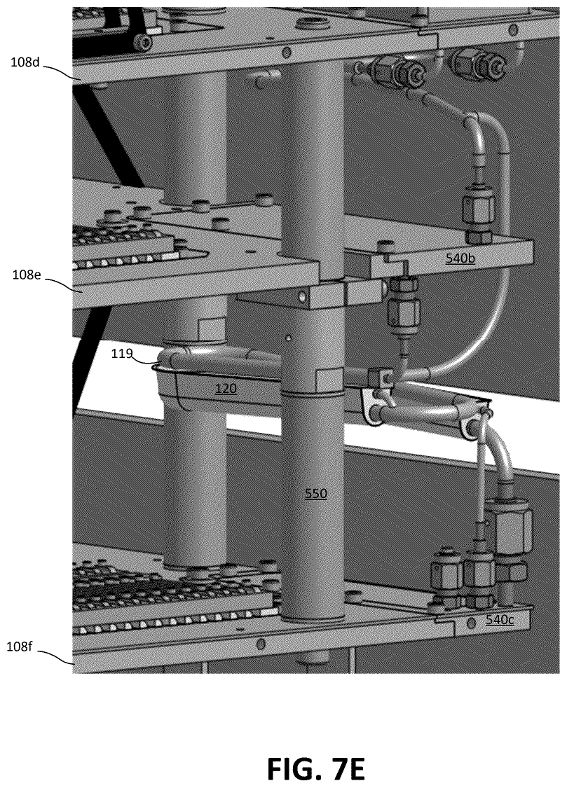

The inventors have additionally recognized and appreciated that the user experience may be improved by allowing users to easily swap parts in and out of the dilution refrigerator 100 (e.g., for maintenance, to change the characteristics of the dilution refrigerator 100, and/or to upgrade the dilution refrigerator 100 as technological innovations are developed). The inventors have accordingly developed a swappable dilution insert that is easily removed and replaced. FIG. 7A shows illustrative components of a removable dilution insert 540 for the dilution refrigerator 100 of FIG. 3, in accordance with some embodiments described herein.

In some embodiments, the removable dilution insert 540 includes detachable plates 540a, 540b, 540c removably coupled to thermal stages 108d, 108e, and 108f, respectively. As shown in the example of FIG. 7A, the detachable plates 540a, 540b, and 540c may be removably coupled using mechanical fasteners (e.g., bolts and/or screws). In some embodiments, the removable dilution insert 540 further includes detachable connections 540d above the still (e.g., flanges) and to the condensing line 102a to further simplify replacement of the removable dilution insert 540.

FIG. 7B shows a close-up view of a detachable plate 540b of the removable dilution insert of FIG. 7A, in accordance with some embodiments described herein. The detachable plate 540b includes an input A and an outlet B to allow helium to flow through the detachable plate 540b, in some embodiments.

In some embodiments, the detachable plates 540a, 540b, and/or 540c may include integrated heat exchangers. In some embodiments, the integrated heat exchangers may be channels 542 formed in the detachable plates 540a and/or 540b, as illustrated by the example of FIG. 7C, which shows a cross section through the detachable plate 540b of FIG. 7B. The channels 542 may be configured to have a high surface area. By allowing helium to flow through the channels 542 in the detachable plates 540a and/or 540b, the helium's rate of cooling may be increased. In some embodiments, the channels 542 may be formed by machining, welding, and/or by additive fabrication techniques (e.g., three-dimensional printing techniques).

In some embodiments, the integrated heat exchangers may be a high surface area material structure formed in the detachable plate 540c. For example, the integrated heat exchangers may be a lattice structure, as shown in the example of FIG. 7D. The lattice structure may be, as a non-limiting example, a square lattice structure having a periodicity in a range from approximately 400 μm to approximately 1000 μm. For example, the lattice structure may have a periodicity of approximately 600 μm.

In some embodiments, the lattice structure may be fabricated using additive fabrication techniques (e.g., three-dimensional printing techniques). The lattice structure may be fabricated to have a rough surface texture to increase the surface area of the material in contact with the helium mixture passing through the integrated heat exchanger, thereby improving heat exchange. In some embodiments, the lattice structure may be formed of a metal. As non-limiting examples, the lattice structure may be formed of copper, silver, and/or aluminum.

In some embodiments, the dilution insert 540 may include one or more heat exchangers, as described in connection with dilution refrigerator 100 of FIG. 3. FIG. 7E shows an illustrative implementation of a continuous heat exchanger 119 and discrete heat exchanger 120, in accordance with some embodiments described herein. As shown in FIG. 7E, the helium flows from the detachable plate 540b coupled to fifth thermal stage 108e into the continuous heat exchanger 119 followed by the discrete heat exchanger 120 and the detachable plate 540c.

Refrigeration cycles in cryogenic coolers typically use a method to control the flow of heat throughout the system. This control may be achieved with a superconductor, a gas gap, or other mechanisms to make or break a thermal connection between components within the system (i.e., heat switches). One common type of heat switch, a gas gap, typically comprises two high surface area objects with a small gap between them that is filled with a gas. As the system falls below a certain temperature, the conductive gas is adsorbed onto surface area in the heat switch, creating a vacuum and reducing heat transfer between the surfaces. Another common type of heat switch is a superconducting switch where a material passes through a superconducting transition and reduces thermal conductivity.

In some embodiments, the dilution refrigerator 100 may further include combined gas gap and/or superconducting heat switches between thermal stages of the dilution refrigerator 100. The example of FIG. 7E shows such a combined gas gap and superconducting heat switch 550 thermally coupled between thermal stages 108e and 108f. The combined gas gap and superconducting heat switches 550 include both a superconducting material (e.g., aluminum, titanium) that becomes superconducting at a temperature higher than a target temperature of the thermal stage to which it is thermally coupled and a gas gap heat switch to improve thermal isolation between the thermal stages.

Returning to FIG. 3, after the ³He/⁴He mixture exits the discrete heat exchanger 120, it passes through the sixth thermal stage 108f and enters the mixing chamber 122. In the mixing chamber 122, ³He atoms may be pumped from a concentrated phase into a dilute phase (i.e., mixed with ⁴He). This mixing causes the ³He to be cooled as it passes through the phase transition between the concentrated phase to the dilute phase, and this endothermic phase transition provides the final cooling power of the dilution refrigerator 100.

In some embodiments, an experimental volume 124 (e.g., a sample stage or plate) may be thermally coupled to the mixing chamber 122 and configured to support a sample and/or quantum device. Because the experimental volume 124 is thermally coupled to the mixing chamber 122, the sample and/or quantum device may be held at or near the mixing chamber temperature.

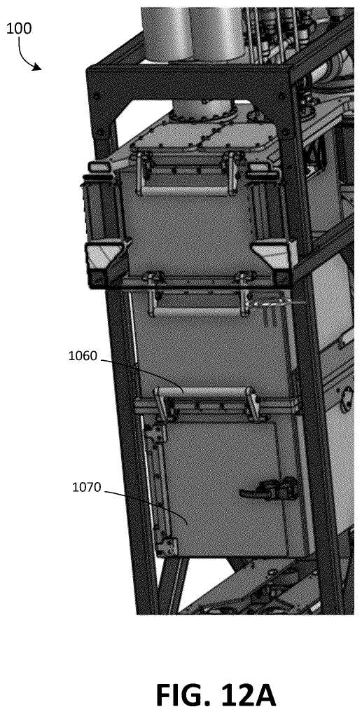

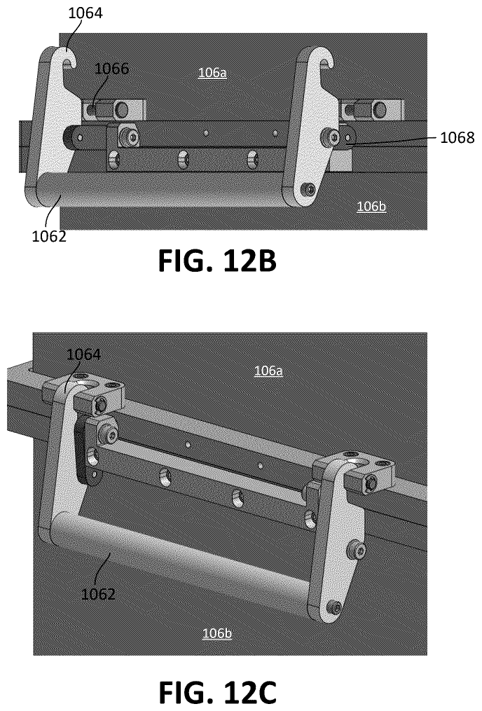

In some embodiments, the experimental volume 124 may be accessed by the user when the dilution refrigerator 100 is not in operation through an opening in the vacuum chamber 106 and door 125. The door 125 may be, in some embodiments, a removable panel (e.g., secured with mechanical fasteners) or may be a hinged door that a user may open using a clamped handle (e.g., as shown in the example of FIG. 12A herein).

As illustrated in the example of FIG. 3, certain components of the dilution refrigerator 100 may be thermally coupled to a thermal stage and disposed on one side (e.g., above or below) the thermal stage. For example, the still 114 is shown as being disposed on a lower surface of the fourth thermal stage 108d. It should be appreciated that in some embodiments, such components may be disposed on either side of the associated thermal stage, as aspects of the technology described herein are not limited in this respect. For example, in some embodiments the still 114 may be disposed on an upper surface of the fourth thermal stage 108d. As another example, the helium cleaning devices 110 may be disposed on a lower surface of the first thermal stage 108a, in some embodiments.

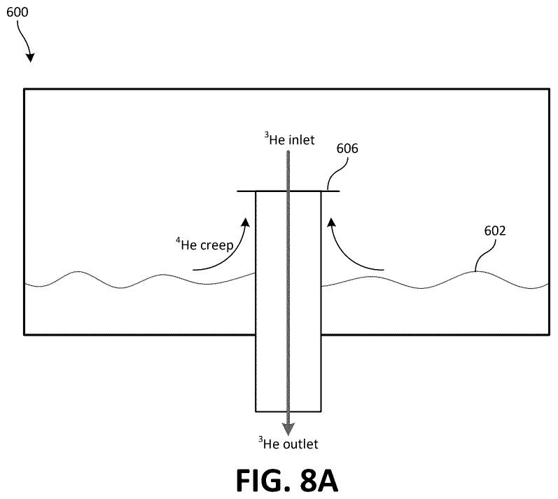

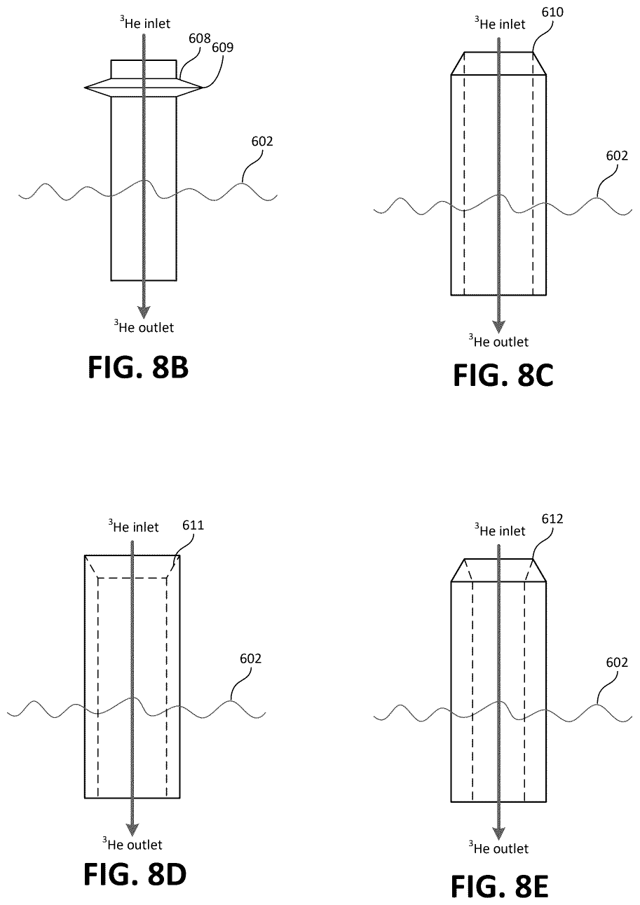

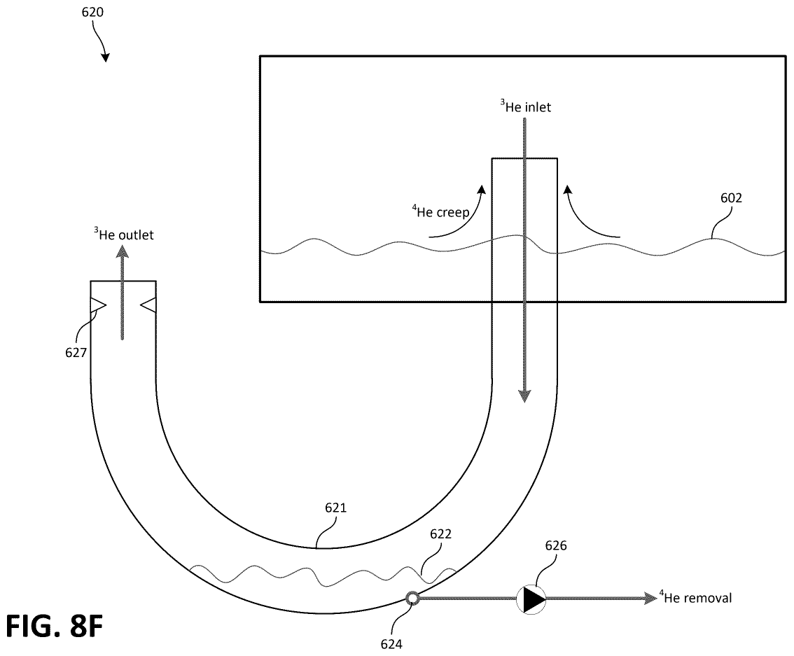

In some embodiments, after entering the dilute phase, the ³He/⁴He mixture may be pumped out of the mixing chamber 122 and back through the dilution refrigerator 100, exiting the outer vacuum chamber 106 through return 102b. At low temperatures and pressures, ⁴He forms a thick and mobile film that can move long distances across surfaces, including moving in a direction counter to the force of gravity. This helium creep can result in ⁴He entering portions of a dilution refrigeration system where it is unwanted (e.g., spanning the gap between thermally isolated areas). FIGS. 8A-8F are schematic diagrams of exemplary ⁴He separation devices that may be implemented at outlets in, for example, the mixing chamber 122 and/or the still 114, in accordance with some embodiments described herein.

FIG. 8A illustrates a cooling stage 600 (e.g., a still, the mixing chamber, etc.) including a bath 602 of a dilute phase helium mixture (e.g., a ³He/⁴He mixture), in some embodiments. ⁴He can creep up an outlet pipe (e.g., a still pumping outlet pipe, a mixing chamber outlet pipe) and exit the cooling stage 600 unless a barrier 606 prevents the helium creep. In the example of FIG. 8A, barrier 606 comprises a sharp edge at a right-angled surface configured to prevent helium from exiting the cooling stage 600 through the low pressure pumping outlet.

Other embodiments of a barrier configured to prevent ⁴He creep are shown in the examples of FIGS. 8B, 8C, 8D, and 8E. In the example of FIG. 8B, a ring 608 with a knife edge 609 is configured to prevent ⁴He from exiting through the ³He outlet. In some embodiments, the ring 608 may include a heating device (e.g., a resistive heater or any other suitable heater) configured to cause the creeping ⁴He to leave the superfluid phase, thereby mitigating creep.

In the examples of FIGS. 8C, 8D, and 8E, vertical knife edges are used to prevent ⁴He from exiting through the ³He outlet. In some embodiments, and in the example of FIG. 8C, the knife edge 610 is on the exterior circumference of the outlet pipe. Alternatively, as shown in the example of FIG. 8D, the knife edge 611 may be beveled on the interior circumference of the outlet pipe. Further, as shown in the example of FIG. 8E, the knife edge 612 may be beveled on both the exterior and interior circumferences of the outlet pipe.

In some embodiments, and as shown in the example of FIG. 8F, the ³He outlet may include a p-trap 621 configured to collect ⁴He 622 at a lower surface of the p-trap 621. The ³He outlet may include a normal leak or a superleak 624 configured to allow normal or superfluid ⁴He to exit the p-trap 621, and a pump 626 (e.g., a fountain pump) may transport the ⁴He away from the p-trap 621. In some embodiments, a further barrier 627 may be present on an interior surface of the outlet pipe. For example, the barrier 627 may be configured as a ring. In some embodiments, the barrier 627 may include a heating device to further prevent ⁴He from exiting the outlet.

The inventors have recognized and appreciated that nanomaterials can provide advantages compared to conventional sintered metal powders (e.g., silver and/or copper powder) used in typical discrete heat exchangers. Accordingly, the inventors have developed nanomaterial heat exchangers that provide efficient heat exchange because of the nanomaterials' large surface area, high mechanical contact strength, and good neck growth between nanowires.

Typical discrete heat exchangers are commonly made out of sintered metal power (e.g., silver and/or copper powder). An example of such sintered particulates is shown in FIG. 9A. To have efficient heat exchange at the sub-Kelvin temperatures, however, a number of factors must be true with regards to the heat exchanger materials. The heat exchange material should have a large surface area, provide high mechanical and/or thermal contact between the liquid helium and the heat exchange material, allow for good neck growth, and provide space inside the heat exchange material for the liquid helium to move through the heat exchanger.

FIG. 9B shows an image of a nanomaterial comprising nanowires for use in a heat exchanger. FIG. 9C shows an image of a nanomaterial comprising nanoclusters for use in a heat exchanger. FIG. 9D shows images of nanomaterials comprising different examples of nanopellet shapes for use in a heat exchanger, in accordance with some embodiments described herein. These nanomaterials may be implemented in dilution refrigerator 100 in discrete heat exchanger 120 and/or in a block heat exchanger (e.g., present in the mixing chamber 122). It should be appreciated that FIGS. 9B-9D show examples of nanomaterial shapes, but that embodiments of nanomaterial for use in a discrete heat exchanger are not so limited. For example, the nanomaterial may alternatively be a nanofoam, nanotube, and/or any other suitable nanoshape.

In some embodiments, such a nanomaterial-based heat exchanger may be formed by bonding the nanomaterial through sintering. For example, the nanomaterial may be formed as a chemical precipitate and/or by electronic deposition or electroplating techniques. A substrate with a rough surface (e.g., comprising nucleation sites) may be provided for the nanomaterial to be grown on or adhered to. In some embodiments, the heat exchanger may be produced under heat and/or compression. The nanomaterial may be held in compression during the sintering process to form the nanowire heat exchanger. In some embodiments, the substrate may be patterned with macroscopic structures (e.g., a lattice or series of posts). In some embodiments, the substrate may be a tube, and the nanomaterial may be adhered to the interior or exterior surface of the tube. In some embodiments, the substrate may be formed of a material with a lower thermal conductivity than the nanomaterial adhered to the substrate.

In some embodiments, the nanomaterial may be formed out of one of a selection of vacuum-compatible materials including but not limited to copper, silver, vacuum-compatible polymers, carbon, and/or carbon fiber. For example, the nanomaterial may be nanowires comprising at least one of copper nanowires, silver nanowires, gold nanowires, platinum nanowires, polymer nanowires, carbon nanowires, and/or carbon fiber nanowires.

III. Vibration Isolation

Many experiments conducted at sub-Kelvin temperatures are sensitive to vibrational noise both from the surrounding environment and the dilution refrigerator's cooling system pumps and components. Additionally, at sub-Kelvin temperatures, mechanical vibrations can generate a heat load, reducing the cooling power of the dilution refrigerator or producing tribo-electric noise on electrical inputs and/or outputs of the dilution refrigerator. The inventors have recognized and appreciated that improved vibration isolation can improve the cooling power and other performance characteristics (e.g., magnetic flux disruption) of a dilution refrigerator. Accordingly, the inventors have developed vibration isolation components configured to mechanically decouple the lower thermal stages 108d-108f from the upper thermal stages 108a-108c.

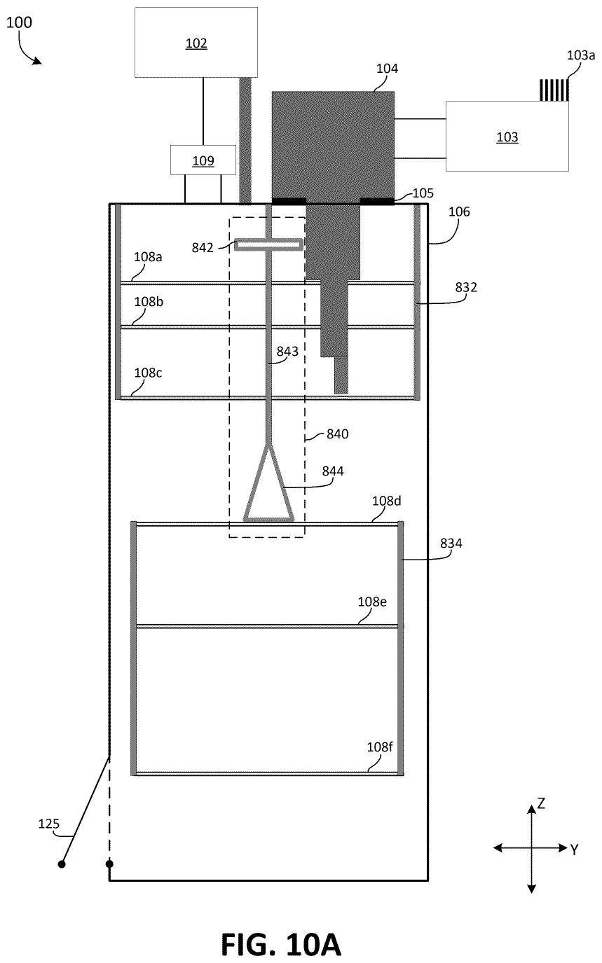

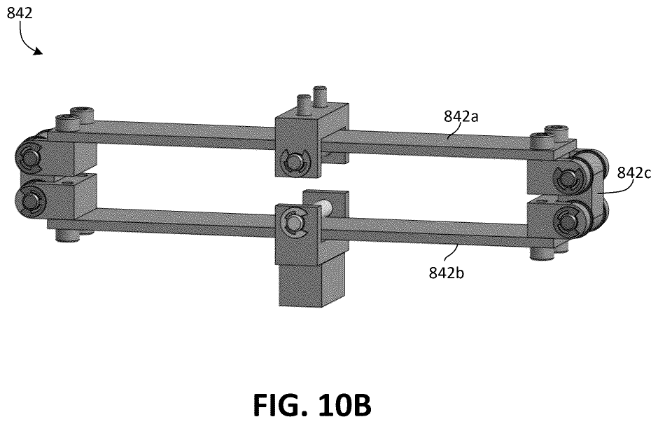

FIG. 10A shows another schematic diagram of dilution refrigerator 100 including mechanical elements configured to provide vibration isolation, in accordance with some embodiments described herein. The vibration isolation elements include a first suspension system 832, at least one second suspension system 840, and a third suspension system 834.

In some embodiments, the first suspension system 832 may be configured to suspend the first thermal stage 108a, the second thermal stage 108b, and/or the third thermal stage 108c from the top surface of the outer vacuum chamber 106. The first suspension system 832 may include one or more rods configured to rigidly couple the first, second, and/or third thermal stages 108a-108c to the top surface of the outer vacuum chamber 106. The rods may be formed of a material having a high spring constant. For example, the rods may be formed of carbon fiber and/or stainless steel.

In some embodiments, the second suspension system 840 may be configured to independently suspend the fourth thermal stage 108d, the fifth thermal stage 108e, and/or the sixth thermal stage 108f from the top surface of the outer vacuum chamber 106. This independent suspension of the lower thermal stages 108d-108f vibrationally isolates the lower thermal stages 108d-108f from the upper thermal stages 108a-108c, thereby improving the vibration isolation of the lower thermal stages 108d-108f.

In some embodiments, the second suspension system 840 may include one or more springs 842, rods 843, and/or connectors 844. While the example of FIG. 10A shows only one second suspension system 840, it should be appreciated that multiple second suspension systems 840 may be used to suspend the lower thermal stages 108d-108f, in some embodiments. For example, there may be two, three, or four such second suspension systems 840, in some embodiments.

In some embodiments, the springs 842 may be configured to provide a constant spring tension under different loads (e.g., for different dampened masses hanging from the springs 842). An example of a spring 842 is shown in FIG. 10B. The springs 842 may be leaf suspension springs, in some embodiments, and may include an upper flexure 842a separated from a lower flexure 842b by rigid portions 842c. The springs 842 may flex through the flexing of upper and lower flexures 842a, 842b, providing vibrational isolation to the lower thermal stages 108d-108f along the Z axis (e.g., perpendicular to a plane of the floor supporting the dilution refrigerator 100). In some embodiments, a spring constant of the spring 842 may be determined by pre-tensioning the upper and/or lower flexures 842a, 842b. Alternatively or additionally, the spring constant of the spring 842 may be determined by changing a length of the upper and/or lower flexures 842a, 842b (e.g., having a lower spring constant for longer lengths of flexures 842a, 842b).

In some embodiments, the springs 842 may be coupled to the third thermal stage 108d by rods 843. The rods 843 may be soft rods having a low spring constant. For example, the rods 843 may be formed out of a polymer (e.g., DELRIN), in some embodiments. The rods 843, due to their softness, may provide vibrational isolation to the lower thermal stages 108d-108f in the X-Y plane (e.g., in a plane parallel to a plane of the floor supporting the dilution refrigerator 100 and perpendicular to the Z axis).

In some embodiments, the connectors 844 may be arranged in a triangular configuration to provide stability to the suspension of the fourth thermal stage 108d. The connectors 844 may be made of materials configured to have a high spring constant. For example, the connectors 844 may be formed of stainless steel and/or carbon fiber.

In some embodiments, the third suspension system 834 may be configured to suspend the fifth thermal stage 108e and the sixth thermal stage 108f from the fourth thermal stage 108d. In this manner, the three lower thermal stages 108d-108f may all be suspended from the top surface of the vacuum chamber 106 using the second suspension system 840. The third suspension system 834 may include one or more rods configured to rigidly couple the fifth and/or sixth thermal stages 108e, 108f to the fourth thermal stage 108d. The rods may be formed of a material having a high spring constant. For example, the rods may be formed of carbon fiber and/or stainless steel, in some embodiments.

It should be appreciated that while the example of FIG. 10A shows the first and third suspension systems 832, 834 as being formed out of rods, in some embodiments, the first and/or the third suspension system 832, 834 may be formed out of flexible springs, as aspects of the present disclosure are not limited in this respect. Additionally, it should be appreciated that while the example of FIG. 10A shows the second suspension system 840 as being formed out of springs, in some embodiments, the second suspension system 840 may be formed out of rods, as aspects of the present disclosure are not limited in this respect.

### IV. Integrated Dilution Refrigerator

Conventional dilution refrigerator technology often requires large amounts of space and expensive supporting infrastructure such as custom-built floating foundations, high ceilings, and/or access pits. These infrastructure requirements may reduce the scalability of quantum technologies that operate at low temperatures. As a non-limiting example, the adoption of certain quantum computing technologies may be limited by the required use of large dilution refrigerators. The inventors have recognized and appreciated that reducing the size and infrastructure requirements of dilution refrigerators may enable the scalability of quantum technologies. The inventors have further recognized that integrating dilution refrigerators with commercial computing infrastructure (e.g., commercial server infrastructure) can further enable the scalability of dilution refrigerators and associated quantum technologies dependent on dilution refrigerators. Such integrated dilution refrigerators may be more easily integrated into telecommunications networks, can use existing telecommunications heat removal architectures, and integrate with fiberoptic networks and systems.

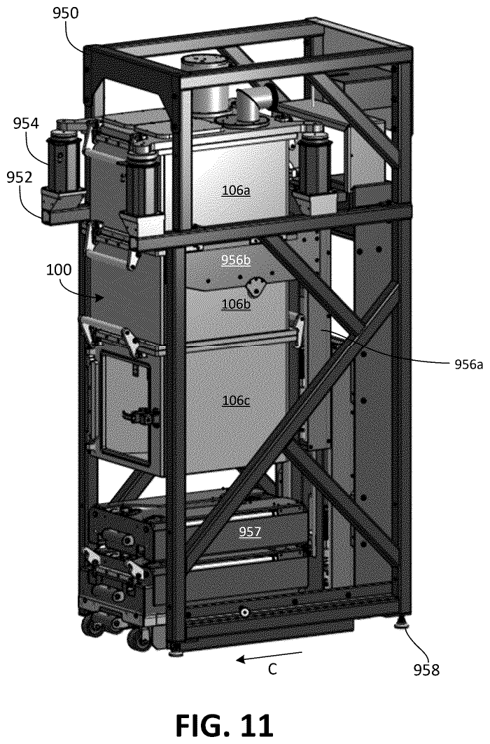

FIG. 11 is a side view of an illustrative external support rack 950, in accordance with some embodiments described herein. In some embodiments, the external support rack 950 may support the dilution refrigerator 100 by suspending the dilution refrigerator 100 off of the floor below the dilution refrigerator 100. As shown in the example of FIG. 11, the external support rack 950 may include arms 952 that are coupled to portions of the top surface of the vacuum chamber 106 by vibration isolation components 954 to suspend the dilution refrigerator 100 off of the floor. In some embodiments, the vibration isolation components 954 may be air pistons, electromagnetic dampeners, and/or springs.

In some embodiments, the external support rack 950 may include castors (not shown) configured to assist in transportation of the dilution refrigerator 100. The castors may be retractable such that the wheels of the castors are not in contact with the floor supporting the external support rack 950 when the dilution refrigerator 100 is not being transported and/or is in operation.

In some embodiments, the external support rack 950 further includes floor supports 958. Floor supports 958 may be configured to extend from the external support rack 950 when the dilution refrigerator 100 is not being transported. Floor supports 958 may extend from the external support rack 950, for example, by the use of screws. The floor supports 958 may be used to lift and/or level the external support rack 950 away from the floor and/or to lift the castors of the external support rack 950 off of the floor. In some embodiments, the floor supports 958 may be used to correct the positioning of the external support rack 950 in the case of an uneven floor surface.

In some embodiments, the external support rack 950 may support additional components external to the outer vacuum chamber 106 of dilution refrigerator 100. For example, the external support rack 950 may house compressors, pumps, and/or cooling equipment configured to support the operation of the dilution refrigerator 100. Alternatively, these external components may be housed in an adjacent (e.g., a different) server rack-type container and/or support rack 950 than the dilution refrigerator 100, in some embodiments.

In some embodiments, the external support rack 950 may include elements configured to provide tool-free assembly and/or disassembly of the vacuum chamber 106 and access to the experimental volume, in accordance with some embodiments described herein. As shown in the example of FIG. 11, the vacuum chamber 106 includes three sections, a first section 106a, a second section 106b suspended from the first section 106a, and a third section 106c suspended from the second section 106b. It should be appreciated that the technology described herein is not limited to three sections, and that a vacuum chamber may have one, two, four, five, or six sections in some embodiments.

In some embodiments, the vacuum chamber 106 may have one or more substantially planar surfaces. In some embodiments, at least one of the one or more substantially planar surfaces may be disposed within a plane perpendicular to a plane of a floor supporting the dilution refrigerator. As shown in the example of FIG. 11, the sections 106a-106c may each have at least four substantially planar surfaces such that, when assembled, the vacuum chamber 106 is arranged to form a rectangular prism. In some embodiments, the vacuum chamber 106 may include two substantially planar surfaces disposed within a plane parallel to the plane of the floor and arranged to close the rectangular prism formed by the surfaces of the sections 106a-106c. In some embodiments, and as described below, the vacuum chamber 106 may have an opening accessible by a door 1070 in at least one of the substantially planar surfaces.

In some embodiments, the three sections 106a-106c of the vacuum chamber 106 may be partially or fully removable in order to provide access to internal portions of the dilution refrigerator 100. For example, the three sections 106a-106c of the vacuum chamber 106 may comprise removable panels (e.g., side panels, panels attached to a frame, etc.), in some embodiments. The three sections 106a-106c may be configured to allow a user of the dilution refrigerator 100 to be able to remove the vacuum chamber 106 from the dilution refrigerator 100 without needed a large clearance above or below the dilution refrigerator 100 (e.g., without needing high ceilings or a pit underneath the dilution refrigerator 100).

In some embodiments, the external support rack 950 may include an integrated lift 956a configured to support the three sections 106a-106c of the vacuum chamber during assembly, disassembly, and/or maintenance of the dilution refrigerator 100. The integrated lift 956a may be configured to raise and/or lower the sections 106a-106c of the vacuum chamber. For example, the integrated lift 956a may be configured to raise and/or lower arms 956b configured to support portions (e.g., the flanges) of the three sections 106a-106c. In some embodiments, the integrated lift 956a may be operated manually (e.g., using screws and/or cables). In some embodiments, the integrated lift 956a may be operated using an electronically-operated machine (e.g., pneumatic or hydraulic devices).

In some embodiments, the external support rack 950 may include one or more carts 957. The carts 957 may be configured to receive one or more of the sections 106a-106c when lowered manually or by using the integrated lift 956a. For example, the integrated lift 956a may be used to lower the third section 106c onto a cart 957. Thereafter, the third section 106c may be transported using the cart 957 along direction C to provide a user of the dilution refrigerator 100 space under the interior components of the dilution refrigerator 100.

In some embodiments, the integrated lift 956a may be removably coupled to the external support rack 950. For example, the integrated lift 956a may be slidably removable from the external support rack 950 (e.g., sliding horizontally outward along the direction C). Removal of the integrated lift 956a may be desired to provide the user with extra space (e.g., during maintenance of the dilution refrigerator 100).

In some embodiments, the three sections 106a-106c of the vacuum chamber 106 may be suspended from one another by integrated clamps and/or cams. Such integrated clamps and/or cams may be configured to enable a user to unclamp or clamp two sections of the three sections 106a-106c together without the use of any additional tools. FIGS. 12A-12C illustrate an example of an integrated cam 1060, with FIG. 12B showing the integrated cam 1060 in an open position and FIG. 12C showing the integrated cam 1060 in a closed position.

In some embodiments, the integrated cam 1060 includes a handle 1062 that enables a user to clamp or unclamp two sections of the three sections 106a-106c together or apart. The handle 1062 is coupled to two latches 1064 that are configured to connect to bars 1066. The handle 1062 and latches 1064 are hingedly coupled to a section of the vacuum chamber 106 by cams 1068, which provide the requisite range of motion to perform clamping and unclamping motions.

In some embodiments, a compressive layer may be included at the connection points between the three sections 106a-106c of the vacuum chamber 106 to ensure a proper vacuum-safe seal. For example, a rubber O-ring, copper or indium gasket, or other vacuum-safe compressive layer may be placed between sections 106a-106c.

Returning to FIG. 12A, in some embodiments, the vacuum chamber 106 may include an external opening to provide access to an internal volume within the dilution refrigerator 100. For example, the opening may provide access to a sample stage or experimental volume of the dilution refrigerator 100, or any other interior portion of the dilution refrigerator 100. In some embodiments, the opening may be sealed by a hermetic seal. In some embodiments, the opening may be sealed by a door 1070, as shown in the example of FIG. 12A. The door 1070 may be sealed, for example, using a hinge and/or a clamp that may be manually engaged and disengaged. In some embodiments, the door 1070 may be coupled to the opening by a load lock.

In some embodiments, the door 1070 may provide access through all of the inner radiation shields (not shown, and which may be thermally coupled to one or more of the thermal stages 108a-108f) of the dilution refrigerator 100 to allow a user to access the experimental volume. For example, a portion of the inner radiation shields (not shown) may be coupled to the door 1070 such that when a user opens the door 1070, the inner radiation shields slide or otherwise move to provide the user access with the interior portion of the dilution refrigerator. In some embodiments, a portion the inner radiation shields may be removable through the door 1070 and/or slidable through the door 1070.

In some embodiments, the external support rack 950 may be configured to be integrated with a server rack-type container. For example, the external support rack 950 may be configured to integrate the dilution refrigerator 100 with commercial server rack infrastructure (e.g., server racks). In some embodiments, the external support rack 950 may be configured to integrate the dilution refrigerator 100 with 19-inch server racks.

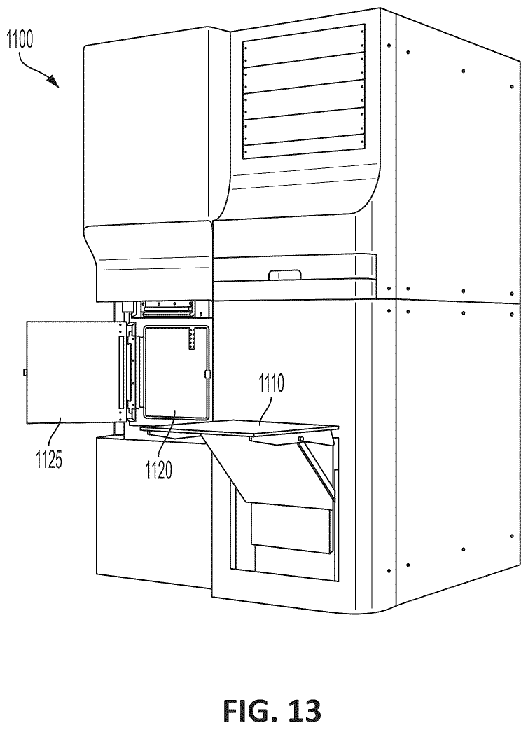

In some embodiments, the external support rack 950 and dilution refrigerator 100 may be housed within an outer housing. An example of an outer housing 1100 is illustrated in FIG. 13. In some embodiments, the outer housing 1100 may include an integrated horizontal surface 1110. For example, the integrated horizontal surface 1110 may be used as a desk or support surface when the user interacts with the dilution refrigerator. The integrated horizontal surface 1110 may be configured to be stowed by folding (as shown in the example of FIG. 13) or sliding away when not in use. In some embodiments, the outer housing 1100 may further include one or more storage locations (e.g., drawers, shelves) for the storage of related parts and/or tools for maintenance of the dilution refrigerator 100.

In some embodiments, the outer housing 1100 may further include a door 1125 providing access through an opening 1120 to the experimental volume of the dilution refrigerator 100. For example, the door 1125 may open to provide access to the experimental volume through the vacuum chamber 106 and the radiation shields inside of the vacuum chamber 106. In some embodiments, the vacuum chamber exterior and/or the radiation shields may be coupled to the door 1125 such that when a user opens the door 1125, the user opens the vacuum chamber exterior 106 and/or the radiation shields. In some embodiments, the radiation shields may alternatively be slidably and/or hingedly movable such that the user may move the radiation shields such that they no longer block access to the experimental volume as needed.

In some embodiments, the housing 1100 may further be configured to perform sound dampening. For example, the housing 1100 may include sound dampening materials to perform passive sound dampening. Alternatively or additionally, the housing 1100 may include audio equipment (e.g., speakers) configured to provide active sound dampening through the emission of destructive interference of the sounds generated by functional components of the system.

### V. Inverted Dilution Refrigerator

Conventionally, dilution refrigerators are oriented such that warmer thermal stages are positioned towards the top of the system with the thermal stages getting increasingly colder as the ³He/⁴He mixture progresses to the bottom of the dilution refrigerator. The inventors have recognized and appreciated that an inverted geometry, with the coldest stage disposed at the top of the system (e.g., furthest from the floor) may simplify the operation and use of a dilution refrigerator by making the experimental volume more accessible to a user and offer improved thermodynamic qualities compared to a conventional dilution refrigerator. Accordingly, the inventors have developed an inverted, dry dilution refrigerator.

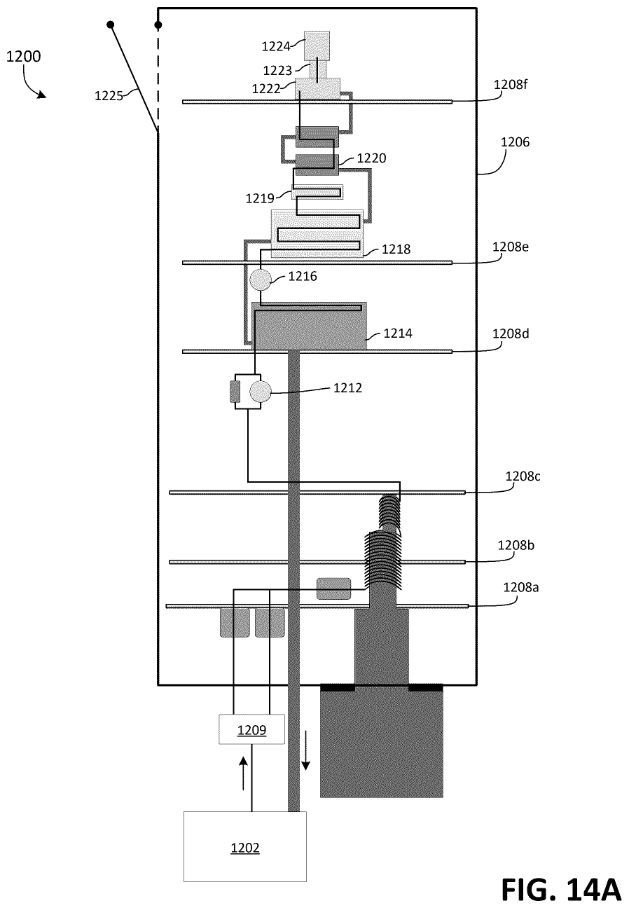

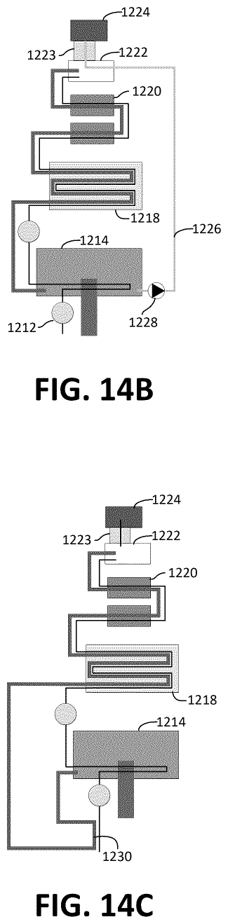

FIG. 14A is a schematic diagram of an inverted dilution refrigerator 1200, in accordance with some embodiments described herein. The inverted dilution refrigerator 1200 may include a pump system 1202 configured to circulate the ³He/⁴He mixture through the dilution refrigerator 1200. The inverted dilution refrigerator 1200 also may include a cryocooler 1204. The cryocooler may be coupled to a cryocooler support (not pictured) as described in connection with cryocooler support 103 herein.

In some embodiments, the inverted dilution refrigerator 1200 may include an outer vacuum chamber 1206 and a series of thermal stages 1208a-1208f disposed inside of the outer vacuum chamber 1206. The series of thermal stages 1208a-1208f may be held at same or similar temperatures as the thermal stages 108a-108f described in connection with FIG. 3 herein.

In some embodiments, the inverted dilution refrigerator 1200 may include an opening in the outer vacuum chamber 1206 and/or through the inner radiation shields to provide ease of access to the coldest stage of the inverted dilution refrigerator 1200. In some embodiments, the opening may comprise hermetic seals and/or an opening mechanism 1225 that may withstand the vacuum within the outer vacuum chamber when the inverted dilution refrigerator 1200 is in operation. For example, the opening mechanism 1225 may include a hinged door and/or a removable panel.

In some embodiments, the inverted dilution refrigerator 1200 may include a number of components arranged along the length of the dilution refrigerator (e.g., from within the vacuum chamber 1206 to within the sixth thermal stage 1208f). The components may be arranged with the coldest thermal stage, the mixing chamber 1224, disposed above warmer thermal stages (e.g., the still 1214, impedance stages 1212 and 1216, heat exchangers 1218, 1219, 1220, etc.).

In some embodiments, the inverted dilution refrigerator 1200 includes a de-mixing chamber 1222 coupled to the mixing chamber 1224. In some embodiments, the de-mixing chamber 1222 may be thermally coupled to the mixing chamber 1224 by a heat exchanger 1223 (e.g., a co-flow heat exchanger). The de-mixing chamber 1222 may be fluidly connected to the mixing chamber 1224 such that ³He may be transported from the de-mixing chamber 1222 to the mixing chamber 1224 to provide additional cooling to the mixing chamber 1224. The de-mixing chamber 1222 may additionally have ⁴He injected into the de-mixing chamber 1222 to provide a co-flow of ³He and ⁴He in order to mitigate a concentration gradient forming between the still 1214 and the mixing chamber 1224.

FIGS. 14B and 14C are schematic diagrams of exemplary internal components of an inverted dilution refrigerator, in accordance with some embodiments described herein. It should be appreciated that the exemplary components of FIGS. 14B and 14C could be implemented within inverted dilution refrigerator 1200 of FIG. 14A (e.g., within the third thermal stage 1208c).

As shown in the example of FIG. 14B, in some embodiments the inverted dilution refrigerator may include a ⁴He line 1226 configured to transport ⁴He from the still 1214 to the de-mixing chamber 1222. In some embodiments, the ⁴He line 1226 may include a pump 1228 configured to assist in the transportation of the ⁴He to the de-mixing chamber 1222. The pump 1228 may be, for example, a fountain pump in some embodiments. Alternatively or additionally, the ⁴He line 1226 may include additional heat exchangers to cool the ⁴He as it travels to the de-mixing chamber 1222.

As shown in the example of FIG. 14C, in some embodiments, the inverted dilution refrigerator may include a heat exchange stage 1230 configured to cool the incoming ³He/⁴He mixture prior to the primary impedance stage 1212. As should be appreciated from the description of FIG. 3, such a configuration may increase the efficiency of the first impedance stage and/or eliminate or reduce the need for pressurization of the incoming ³He/⁴He mixture.

### VI. Distributed Cooling

Dilution refrigerators generally include an integrated cryocooler (e.g., such as a pulse tube or a Gifford-McMahon cryocooler) to pre-cool the ³He/⁴He mixture gas below 5 K. Conventionally, a dilution refrigerator is paired with at least one of these cryocoolers, and dilution refrigerators do not share cooling systems. Such small-scale dilution refrigeration systems typically rely on low-power cryocooling systems that are relatively inefficient (e.g., requiring more power for each Watt of cooling power at 4 K) in comparison to larger, higher-power cryocooling systems. The inventors have recognized and appreciated that a single, high-efficiency cooling system may be thermally coupled to multiple cryogenic systems such as dilution refrigerators to distribute this first stage of cooling across multiple cryogenic systems. Such distributed cooling therefore allows for increased cooling efficiency across multiple cryogenic systems.

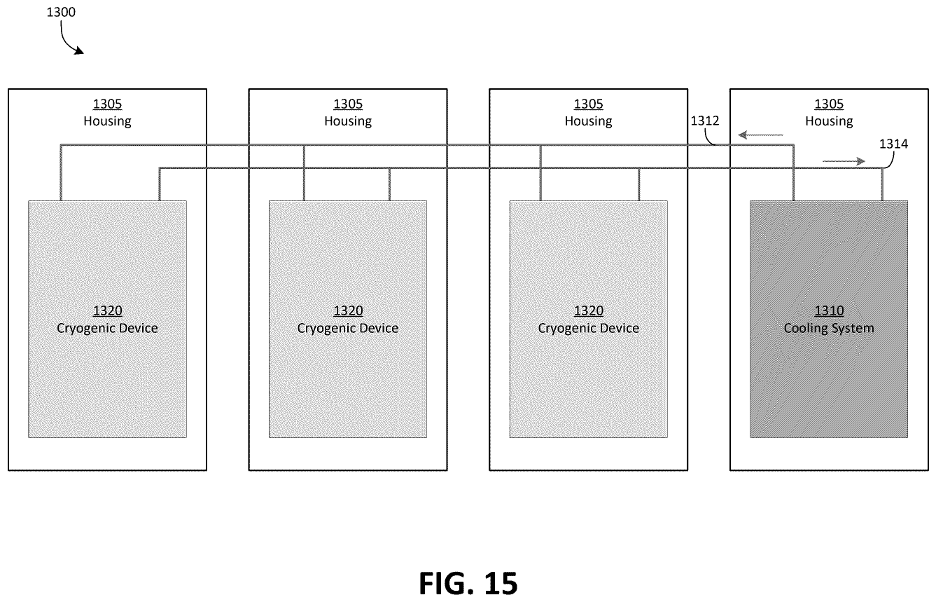

FIG. 15 is a schematic diagram of a distributed cooling system 1300, in accordance with some embodiments described herein. The distributed cooling system 1300 may include multiple housings 1305. In some embodiments, the housings 1305 may be server rack-type containers (e.g., commercial server rack infrastructure, 19-inch server racks).

As shown in the example of FIG. 15, each housing 1305 may contain a cooling system 1310 or a cryogenic device 1320. It should be appreciated that cryogenic devices 1320 and/or cooling systems 1310 may be grouped within housings 1305, in some embodiments. It should further be appreciated that while FIG. 15 shows three cryogenic devices 1320 coupled to the cooling system 1310, in some embodiments, there may be two, four, ten, or many tens of cryogenic devices 1320 coupled to the cooling system 1310, as aspects of this disclosure are not so limited.

In some embodiments, the cooling system 1310 may be a cryocooling system configured to cool a first stage of the cryogenic devices 1320 to a temperature of at least 5 K and/or to a temperature of approximately 4-5 K. In some embodiments, the cooling system 1310 may be a pulse tube. For example, the cooling system 1310 may be a pulse tube, a helium liquefier system, and/or a Brayton cryocooler.

In some embodiments, the cooling system 1310 may be thermally coupled to multiple cryogenic devices 1320. Cooling may be distributed to cryogenic devices 1320 from cooling system 1310 by cooling line 1312. Additionally, heat may be returned from the cryogenic devices 1320 to cooling system by return 1314. The cooling line 1312 and/or return 1314 may be lines configured to transfer liquid and/or gaseous helium. For example, the cooling line 1312 and/or return 1314 may be pipes that are vacuum insulated to maintain the temperature of the transported helium. In some embodiments, the cooling line 1312 and/or return 1314 may be fill lines, heat pipes (e.g., traditional and/or pulsed heat pipes), and/or a superfluid loop.

In some embodiments, the cryogenic devices 1320 may include any suitable refrigeration system configured to reach temperatures at or below 5 K. In some embodiments, cryogenic devices 1320 may include one or more dilution refrigerators (e.g., dilution refrigerator 100 as described herein, configured to reach temperatures below 1 K). Alternatively or additionally, it should be appreciated that cryogenic devices 1320 may include cryogenic systems other than dilution refrigerators (e.g., microscopy systems such as scanning tunneling microscopy or atomic force microscopy systems, ³He refrigeration systems, superconducting CMOS systems, etc.).

In the embodiment shown in FIG. 16, the computer 1400 includes a processing unit 1401 having one or more processors and a non-transitory computer-readable storage medium 1402 that may include, for example, volatile and/or non-volatile memory. The memory 1402 may store one or more instructions to program the processing unit 1401 to perform any of the functions described herein. The computer 1400 may also include other types of non-transitory computer-readable medium, such as storage 1405 (e.g., one or more disk drives) in addition to the system memory 1402. The storage 1405 may also store one or more application programs and/or resources used by application programs (e.g., software libraries), which may be loaded into the memory 1402.

The computer 1400 may have one or more input devices and/or output devices, such as devices 1406 and 1407 illustrated in FIG. 16. These devices can be used, among other things, to present a user interface. Examples of output devices that can be used to provide a user interface include printers or display screens for visual presentation of output and speakers or other sound generating devices for audible presentation of output. Examples of input devices that can be used for a user interface include keyboards and pointing devices, such as mice, touch pads, and digitizing tablets. As another example, the input devices 1407 may include a microphone for capturing audio signals, and the output devices 1406 may include a display screen for visually rendering, and/or a speaker for audibly rendering, recognized text.

As shown in FIG. 16, the computer 1400 may also comprise one or more network interfaces (e.g., the network interface 1410) to enable communication via various networks (e.g., the network 1420). Examples of networks include a local area network or a wide area network, such as an enterprise network or the Internet. Such networks may be based on any suitable technology and may operate according to any suitable protocol and may include wireless networks, wired networks or fiber optic networks. Such networks may include analog and/or digital networks.

### VII. Definitions

Various aspects of the embodiments described above may be used alone, in combination, or in a variety of arrangements not specifically discussed in the embodiments described in the foregoing and is therefore not limited in its application to the details and arrangement of components set forth in the foregoing description or illustrated in the drawings. For example, aspects described in one embodiment may be combined in any manner with aspects described in other embodiments.

All definitions, as defined and used herein, should be understood to control over dictionary definitions, definitions in documents incorporated by reference, and/or ordinary meanings of the defined terms.

The indefinite articles “a” and “an,” as used herein in the specification and in the claims, unless clearly indicated to the contrary, should be understood to mean “at least one.”

The phrase “and/or,” as used herein in the specification and in the claims, should be understood to mean “either or both” of the elements so conjoined, i.e., elements that are conjunctively present in some cases and disjunctively present in other cases. Multiple elements listed with “and/or” should be construed in the same fashion, i.e., “one or more” of the elements so conjoined. Other elements may optionally be present other than the elements specifically identified by the “and/or” clause, whether related or unrelated to those elements specifically identified. Thus, as a non-limiting example, a reference to “A and/or B,” when used in conjunction with open-ended language such as “comprising” can refer, in one embodiment, to A only (optionally including elements other than B); in another embodiment, to B only (optionally including elements other than A); in yet another embodiment, to both A and B (optionally including other elements); etc.

As used herein in the specification and in the claims, the phrase “at least one,” in reference to a list of one or more elements, should be understood to mean at least one element selected from any one or more of the elements in the list of elements, but not necessarily including at least one of each and every element specifically listed within the list of elements and not excluding any combinations of elements in the list of elements. This definition also allows that elements may optionally be present other than the elements specifically identified within the list of elements to which the phrase “at least one” refers, whether related or unrelated to those elements specifically identified. Thus, as a non-limiting example, “at least one of A and B” (or, equivalently, “at least one of A or B,” or, equivalently “at least one of A and/or B”) can refer, in one embodiment, to at least one, optionally including more than one, A, with no B present (and optionally including elements other than B); in another embodiment, to at least one, optionally including more than one, B, with no A present (and optionally including elements other than A); in yet another embodiment, to at least one, optionally including more than one, A, and at least one, optionally including more than one, B (and optionally including other elements); etc.

Use of ordinal terms such as “first,” “second,” “third,” etc., in the claims to modify a claim element does not by itself connote any priority, precedence, or order of one claim element over another or the temporal order in which acts of a method are performed, but are used merely as labels to distinguish one claim element having a certain name from another element having a same name (but for use of the ordinal term) to distinguish the claim elements.

In the claims, as well as in the specification above, all transitional phrases such as “comprising,” “including,” “carrying,” “having,” “containing,” “involving,” “holding,” “composed of,” and the like are to be understood to be open-ended, i.e., to mean including but not limited to. Only the transitional phrases “consisting of” and “consisting essentially of” shall be closed or semi-closed transitional phrases, respectively.

The terms “approximately,” “about,” and “substantially” may be used to mean within ±20% of a target value in some embodiments, within ±10% of a target value in some embodiments, within ±5% of a target value in some embodiments, within ±2% of a target value in some embodiments. The terms “approximately,” “about,” and “substantially” may include the target value.

Having thus described several aspects of at least one embodiment, it is to be appreciated that various alterations, modifications, and improvements will readily occur to those skilled in the art. Such alterations, modifications, and improvements are intended to be part of this disclosure and are intended to be within the spirit and scope of the principles described herein. Accordingly, the foregoing description and drawings are by way of example only.

What is claimed is:

1. A regenerative cryogenic system comprising:
a cryocooler configured to generate cryogenic temperatures;
one or more flanges coupled to the cryocooler; and
a still pumping line integrated with the one or more flanges, the still pumping line configured to provide a flow path for still gas of a dilution refrigerator.

2. The regenerative cryogenic system of claim 1, wherein the cryocooler is configured to generate cryogenic temperatures below 4.2 Kelvin.

3. The regenerative cryogenic system of claim 1, wherein the one or more flanges are configured to provide vacuum interface and/or thermalization.

4. The regenerative cryogenic system of claim 1, further comprising:
a condensing line of the dilution refrigerator integrated with and configured to exchange heat with the cryocooler and the still pumping line,
wherein the condensing line of the dilution refrigerator is configured to condense the still gas of the dilution refrigerator; and
wherein the cryocooler is configured to provide cooling to the condensing line of the dilution refrigerator.

5. The regenerative cryogenic system of claim 4, wherein the condensing line of the dilution refrigerator is integrated with the cryocooler and the still pumping line by wrapping, brazing, or disposition a conduit of the still pumping line within gas flow or within a heat conductive block.

6. The regenerative cryogenic system of claim 4, wherein:
the still pumping line is configured to cool the condensing line of the dilution refrigerator.

7. The regenerative cryogenic system of claim 1, further comprising:
one or more heat exchangers integrated with the cryocooler,
wherein the one or more heat exchangers are configured to provide heat exchange between the dilution refrigerator and the cryocooler.

8. The regenerative cryogenic system of claim 1, wherein the cryocooler comprises one or more pulse tubes.

9. The regenerative cryogenic system of claim 8, wherein the cryocooler further comprises a 4K helium compressor, the regenerative cryogenic system further comprising:
an adsorber replacement system integrated with the 4K helium compressor, wherein the adsorber replacement system is configured to replace an adsorber of the 4K helium compressor without shutting down the 4K helium compressor.

10. The regenerative cryogenic system of claim 8, further comprising:
a helium battery integrated with the cryocooler, wherein the helium battery is configured to store and release helium gas to maintain operation of the regenerative cryogenic system.

11. A method of operating a cryogenic system comprising a cryocooler, a still pumping line of a dilution refrigerator, and a condensing line of the dilution refrigerator, the method comprising:
generating cryogenic temperatures using the cryocooler;
exchanging heat between the condensing line and the cryocooler; and
exchanging heat between the condensing line and the still pumping line.

12. The method of claim 11, wherein generating cryogenic temperatures using the cryocooler comprises:
generating cryogenic temperatures below 4.2 Kelvin.

13. The method of claim 11, further comprising condensing still gas of the dilution refrigerator using the condensing line.

14. The method of claim 11, wherein exchanging heat between the condensing line and the cryocooler comprises:
cooling the condensing line using the cryocooler.

15. The method of claim 11, wherein exchanging heat between the condensing line and the still pumping line comprises:
cooling the condensing line using the still pumping line.

16. The method of claim 11, wherein:
the cryogenic system further comprises one or more flanges configured to provide vacuum interface and/or thermalization;
the one or more flanges are coupled to the cryocooler; and
the still pumping line is integrated with the one or more flanges.

17. A cryogenic system comprising:
means for generating cryogenic temperatures;
one or more flanges configured to provide vacuum interface and/or thermalization, the one or more flanges coupled to the means for generating the cryogenic temperatures; and
a still pumping line integrated with the one or more flanges, the still pumping line configured to provide a flow path for still gas of a dilution refrigerator.

18. The cryogenic system of claim 17, further comprising:
a condensing line of a dilution refrigerator, wherein the condensing line of the dilution refrigerator is configured to:
exchange heat with the means for generating the cryogenic temperatures and the still pumping line; and
condense the still gas of the dilution refrigerator.

19. The cryogenic system of claim 18, wherein:
the condensing line of the dilution refrigerator comprises:
a first portion integrated with and configured to exchange heat with the still pumping line; and
a second portion integrated with and configured to exchange heat with the means for generating the cryogenic temperatures,
the still pumping line is configured to cool the condensing line of the dilution refrigerator.

20. The cryogenic system of claim 18, wherein the condensing line of the dilution refrigerator is integrated with the means for generating the cryogenic temperatures and the still pumping line by wrapping, brazing, or disposition a conduit of the still pumping line within gas flow or within a heat conductive block.
